(19) United States
(12) Patent Application Publication
(10) Pub. No.: US 2026/0343920 A1
(43) Pub. Date: Oct. 29, 2026

(54) Multigate Device and Method of Fabrication Thereof

(71) Applicant: Taiwan Semiconductor Manufacturing Company, Ltd., Hsin-Chu (TW)

(72) Inventors: Chia-Hung Chou, Hsinchu (TW); Chang-Jhih Syu, Hsinchu (TW); Chun-Yen Peng, Hsinchu (TW); Tsung-Da Lin, Hsinchu (TW)

(21) Appl. No.: 19/326,150

(22) Filed: Sep. 11, 2025

Related U.S. Application Data
(60) Provisional application No. 63/794,901, filed on Apr. 25, 2025.

(51) Int. Cl. H10D 30/01; H10D 30/00

(52) U.S. Cl. CPC H10D 30/0193; H10D 30/503

(57) ABSTRACT

Methods of fabricating multigate transistors are disclosed herein. In some embodiments, a method includes forming a multilayer stack that includes semiconductor layers and sacrificial layers, and the sacrificial layers interleave the semiconductor layers. The method further includes, after removing the sacrificial layers, performing a hydrogen treatment to remove residual oxide from exposed surfaces of the semiconductor layers, and after performing the hydrogen treatment, forming a gate that wraps one or more of the semiconductor layers. In some embodiments, the residual oxide is residual germanium oxide, and the hydrogen treatment uses hydrogen radicals and/or H₂ to remove the residual germanium oxide. In some embodiments, the hydrogen treatment modifies and/or shapes the semiconductor layers, and the hydrogen treatment may provide the semiconductor layers with different profiles in different cross-sectional views (e.g., along a gate lengthwise direction and a gate widthwise direction).

This is a non-provisional application of and claims benefit of U.S. Provisional Patent Application Ser. No. 63/794,901, filed Apr. 25, 2025, the entire disclosure of which is incorporated herein by reference.

### BACKGROUND

Recently, multigate devices, which have gates that extend, partially or fully, around a channel to provide access to the channel on at least two sides, have been introduced to improve gate control. Exemplary multigate devices include fin-like field effect transistors (FinFETs) and gate-all around (GAA) transistors, such as nanowire transistors. Multigate devices enable aggressive scaling down of integrated circuit (IC) technologies, maintaining gate control, and mitigating short-channel effects (SCEs), while seamlessly integrating with existing IC manufacturing processes and/or techniques. As multigate devices continue to scale, advanced techniques are needed for optimizing multigate device reliability and/or performance.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method, in portion or entirety, for fabricating a multigate device, according to various aspects of the present disclosure.

FIG. 2 is a top view of a device, in portion or entirety, that may be fabricated by the method of FIG. 1 according to various aspects of the present disclosure.

FIGS. 3A-3Q are diagrammatic cross-sectional views of the device, in portion or entirety, of FIG. 2 along line A-A at various stages of fabrication, such as those associated with the method of FIG. 1, according to various aspects of the present disclosure.

FIGS. 4A-4Q are diagrammatic cross-sectional views of the device, in portion or entirety, of FIG. 2 along line B-B at various stages of fabrication, such as those associated with the method of FIG. 1, according to various aspects of the present disclosure.

FIGS. 5A-5D are diagrammatic cross-sectional views of the device, in portion or entirety, of FIG. 2 along line C-C at various stages of fabrication, such as those associated with the method of FIG. 1, according to various aspects of the present disclosure.

FIG. 6A is a diagrammatic cross-sectional view of a channel region, in portion or entirety, of the device of FIG. 3O, according to various aspects of the present disclosure.

FIG. 6B is a diagrammatic cross-sectional view of a channel region, in portion or entirety, of the device of FIG. 3P, according to various aspects of the present disclosure.

FIG. 7A is a diagrammatic cross-sectional view of a channel region, in portion or entirety, of the device of FIG. 5C, according to various aspects of the present disclosure.

FIG. 7B is a diagrammatic cross-sectional view of a channel region, in portion or entirety, of the device of FIG. 3P, according to various aspects of the present disclosure.

FIG. 8 is a flow chart of another method, in portion or entirety, for fabricating a multigate device, according to various aspects of the present disclosure.

FIGS. 9A-9N are diagrammatic cross-sectional views of another device, in portion or entirety, which may be along line A-A of FIG. 2, at various stages of fabrication, such as those associated with the method of FIG. 1, according to various aspects of the present disclosure.

FIGS. 10A-10N are diagrammatic cross-sectional views of the device of FIGS. 9A-9N, in portion or entirety, which may be along line B-B of FIG. 2, such as those associated with the method of FIG. 1, according to various aspects of the present disclosure.

FIGS. 11A-11D are diagrammatic cross-sectional views of the device of FIGS. 9A-9N, in portion or entirety, which may be along line C-C of FIG. 2, such as those associated with the method of FIG. 1, according to various aspects of the present disclosure.

FIG. 12 is a flow chart of another method, in portion or entirety, for fabricating a multigate device, according to various aspects of the present disclosure.

### DETAILED DESCRIPTION

The present disclosure relates generally to multigate devices, such as gate-all-around transistors, and methods of fabrication thereof for improving overall performance.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Furthermore, when a number or a range of numbers is described with “about,” “approximate,” “substantially,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−20% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Multigate devices include a gate structure that extends, partially or fully, around a channel region to provide access to a channel region on at least two sides. One such multigate device is a gate-all around (GAA) device, which includes channel layers (regions) that are vertically or horizontally stacked and suspended in a manner over a substrate that allows a gate stack to wrap around (or surround) and engage the channel layers. The channel layers extend between a source region and a drain region (e.g., epitaxial source/drains), and voltage can be applied to the gate stack, the source region, and/or the drain region to control flow of current between the source region and the drain region. GAA devices can significantly increase contact area between the gate stack and the channel regions, which may decrease subthreshold swing (SS), decrease short channel effects (SCEs), increase drive current, and/or improve channel control compared to other multigate devices, such as fin-like field effect transistors (FinFETs).

Multigate devices may be fabricated using dummy semiconductor interposers (DSIs) (e.g., sacrificial silicon germanium layers) and/or dummy oxide interposers (DOIs) (e.g., sacrificial dielectric layers) (collectively referred to as dummy interposers) interleaved between semiconductor layers (e.g., silicon layers) in a channel region, which become channels of the multigate device. The dummy interposers may serve as placeholders for subsequently formed gates of the multigate devices. For example, during a gate replacement process, the dummy interposers may be selectively removed to form gaps between the semiconductor layers, and a gate may be formed in the gaps, such that the gate wraps and/or surrounds the semiconductor layers. The present disclosure recognizes that, sometimes, oxide (e.g., germanium oxide) may undesirably remain on the semiconductor layers after removal of the dummy interposers. The present disclosure thus proposes performing a hydrogen thermal treatment (e.g., a hydrogen anneal) after selectively removing the dummy interposers and before forming the gate. The hydrogen thermal treatment is configured (e.g., parameters of the hydrogen anneal, such as temperature, time, etc., are tuned) to remove any residual oxide from the semiconductor layers. In some embodiments, the hydrogen thermal treatment may modify surfaces, profiles, dimensions, and the like of the semiconductor layers. In some embodiments, the hydrogen thermal treatment smooths surfaces of the semiconductor layers, which may reduce line width roughness (LWR) thereof, and/or provides the semiconductor layers with different profiles along different cross-sectional views. The proposed multigate devices and methods for fabricating the multigate devices may improve performance (e.g., improved subthreshold swing and/or improved RO performance) thereof, for example, by reducing short channel effects, reducing interface trap density at channel/gate interfaces, improving channel surface roughness, other improvements, or combinations thereof. Details of the proposed multigate devices (e.g., GAA transistors) and methods for fabricating the multigate devices are described herein in the following pages. From the description herein, it may be seen that multigate devices fabricated according to the methods described in the present disclosure offer advantages over multigate devices fabricated according to other methods. It is understood, however, that other embodiments may offer additional advantages, not all advantages are necessarily disclosed herein, and that no particular advantage is required for all embodiments.

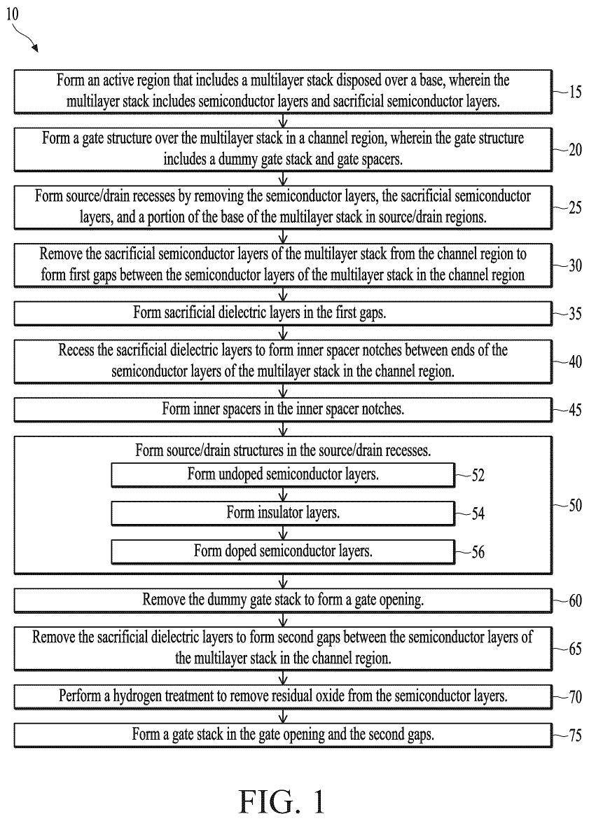

FIG. 1 is a flow chart of a method 10, in portion or entirety, for fabricating multigate devices according to various aspects of the present disclosure. At block 15, method 10 includes forming an active region that includes a multilayer stack disposed over a base (e.g., a portion of a substrate). The multilayer stack includes sacrificial semiconductor layers (e.g., silicon germanium layers) and semiconductor layers (e.g., silicon layers). At block 20, a gate structure may be formed over the multilayer stack in a channel region. The gate structure may include a dummy gate stack and gate spacers. In some embodiments, isolation structures (e.g., shallow trench isolation structures) may be formed adjacent to the base before forming the gate structure. At block 25, source/drain recesses are formed by removing the semiconductor layers, the sacrificial semiconductor layers, and a portion of the base in source/drain regions. Method 10 may further include removing the sacrificial semiconductor layers of the multilayer stack from the channel region to form first gaps between the semiconductor layers of the multilayer stack in the channel region at block 30 and forming sacrificial dielectric layers in the first gaps at block 35. Method 10 may further include recessing the sacrificial dielectric layers to form inner spacer notches between ends of the semiconductor layers of the multilayer stack in the channel region at block 40 and forming inner spacers in the inner spacer notches at block 45. At block 50, method 10 includes forming source/drain structures in the source/drain recesses, which may include forming undoped semiconductor layers at block 52, forming insulator layers at block 54, and forming doped semiconductor layers at block 56. A source/drain structure may thus include one or more doped semiconductor layers disposed over an interposing feature, which may include one or more undoped semiconductor layers, one or more insulator layers, or both. Method 10 may include removing the dummy gate stack to form a gate opening at block 60, removing the sacrificial dielectric layers (also referred to as dummy (and/or disposable) oxide interposers (DOIs)) to form second gaps between the semiconductor layers of the multilayer stack in the channel region at block 65, and forming a gate stack in the gate opening and the second gaps at block 75. Method 10 further includes performing a hydrogen treatment (e.g., a hydrogen anneal) to remove residual oxide from the semiconductor layers at block 70 before forming the gate stack in the gate opening at block 75. In some embodiments, the hydrogen treatment may modify profiles of the semiconductor layers (e.g., by slightly etching the semiconductor layers, thereby modifying dimensions thereof). In some embodiments, a dielectric layer (e.g., an interlayer dielectric layer and/or an etch stop layer) may be formed over the source/drain structures. Additional processing is contemplated by the present disclosure. Additional steps may be provided before, during, and after method 10, and some of the steps described may be moved, replaced, or eliminated for additional embodiments of method 10. The discussion that follows illustrates devices that may be fabricated according to method 10.

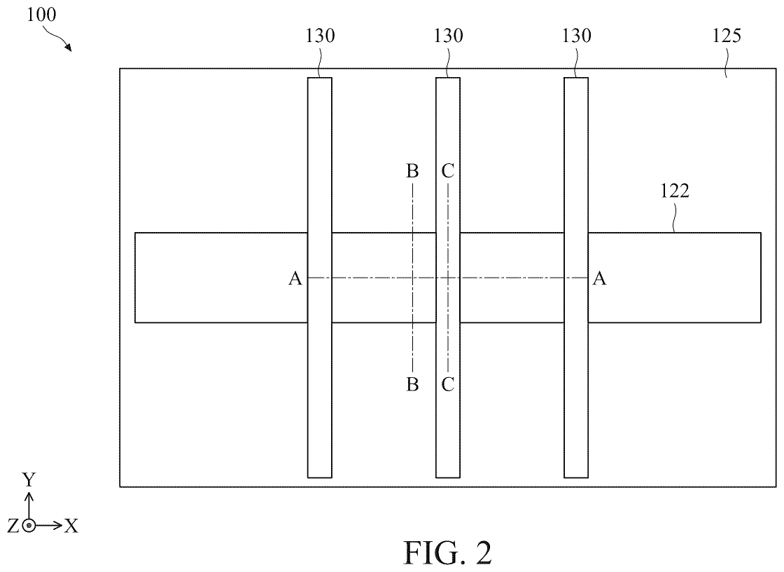

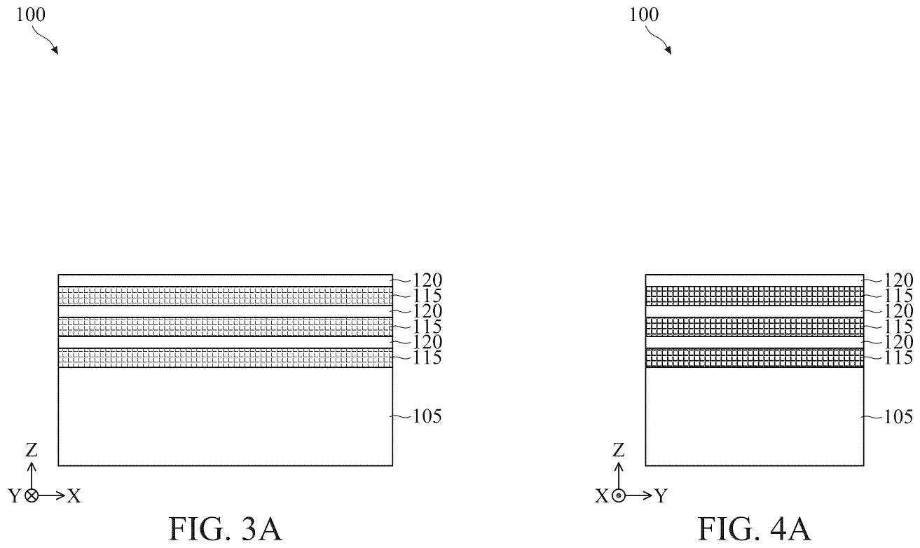

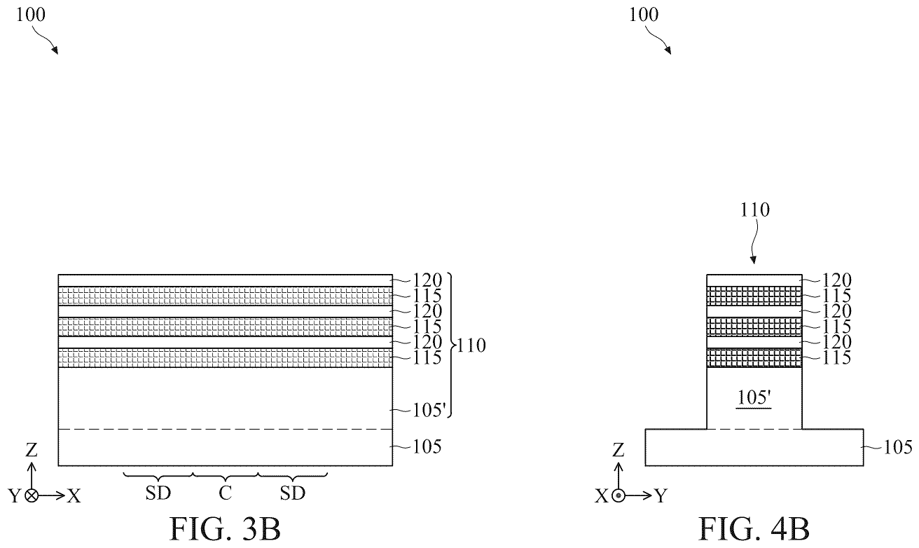

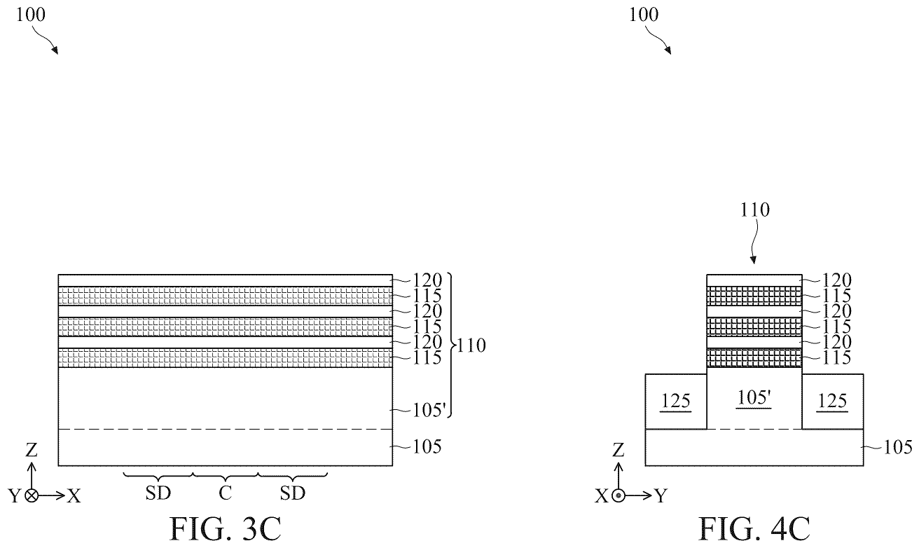

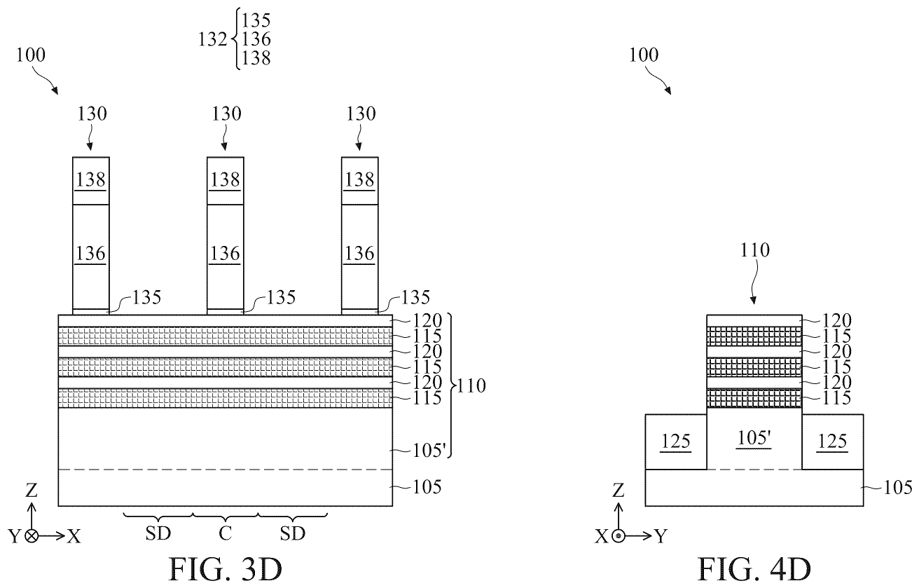

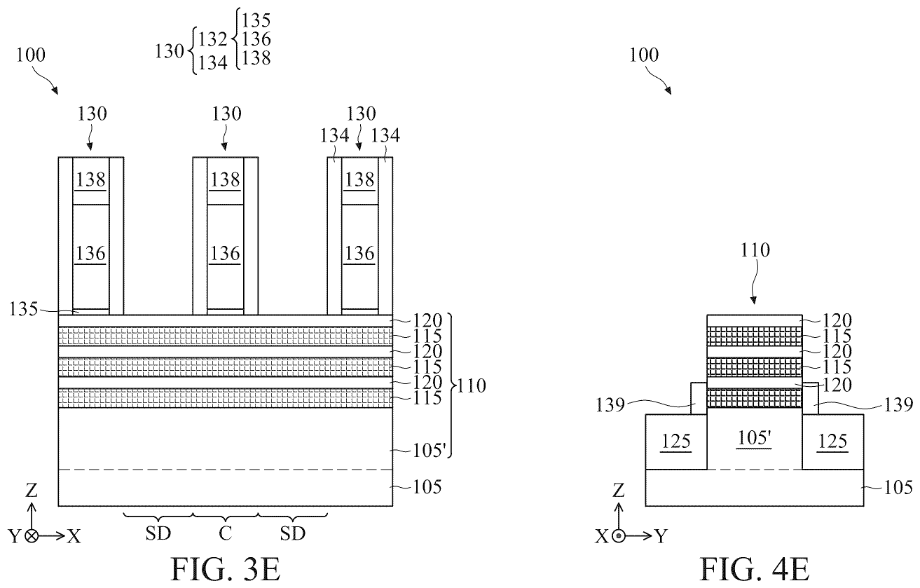

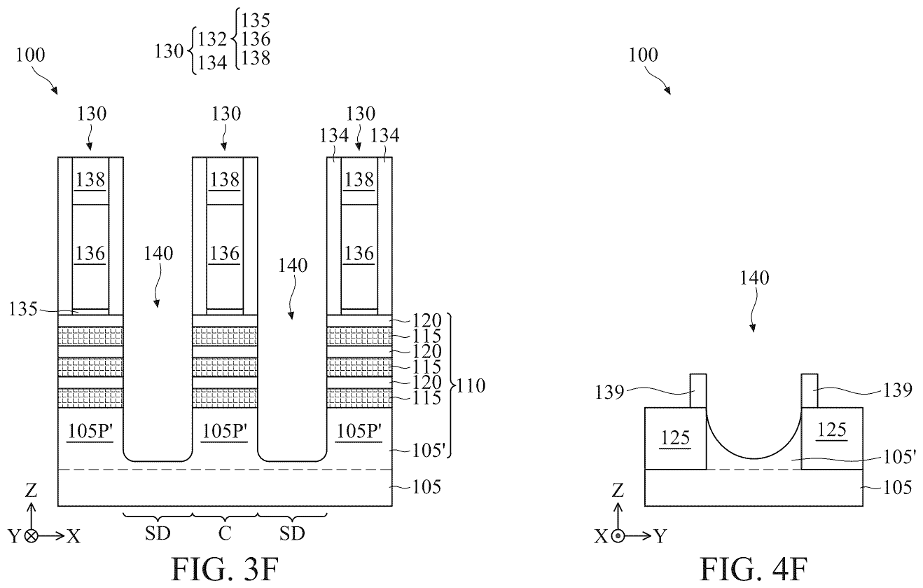

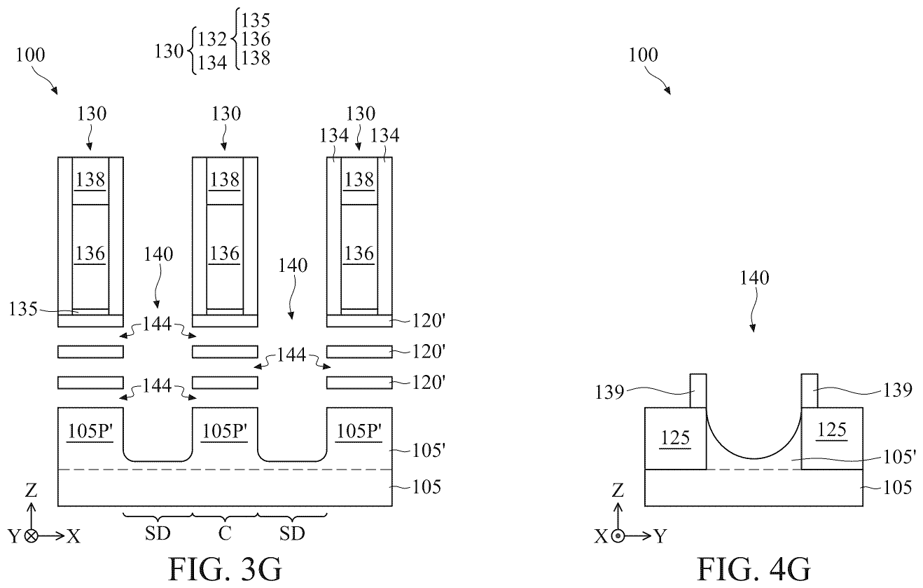

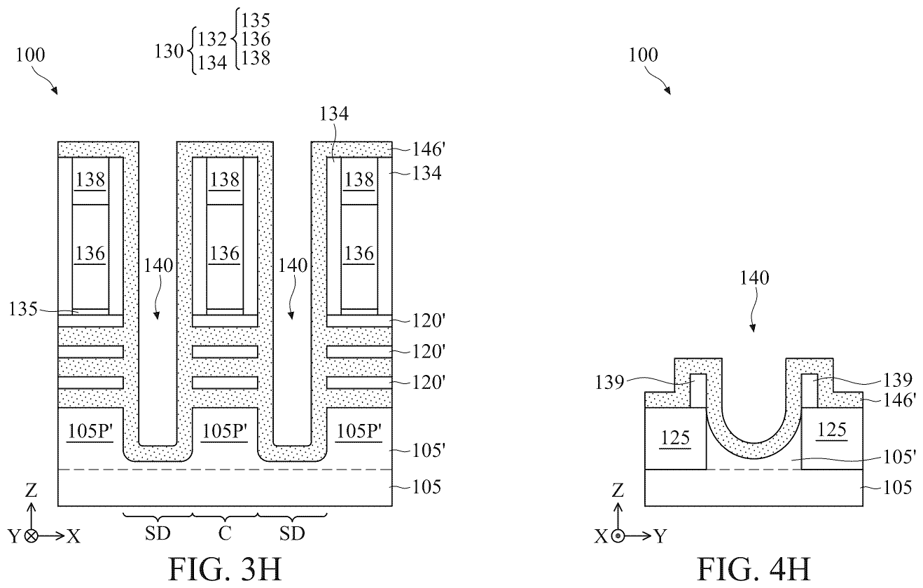

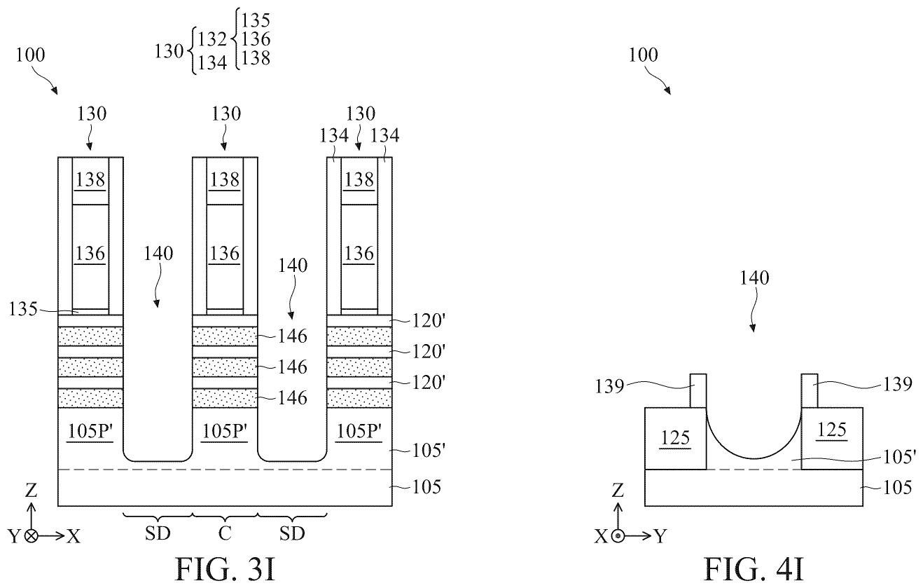

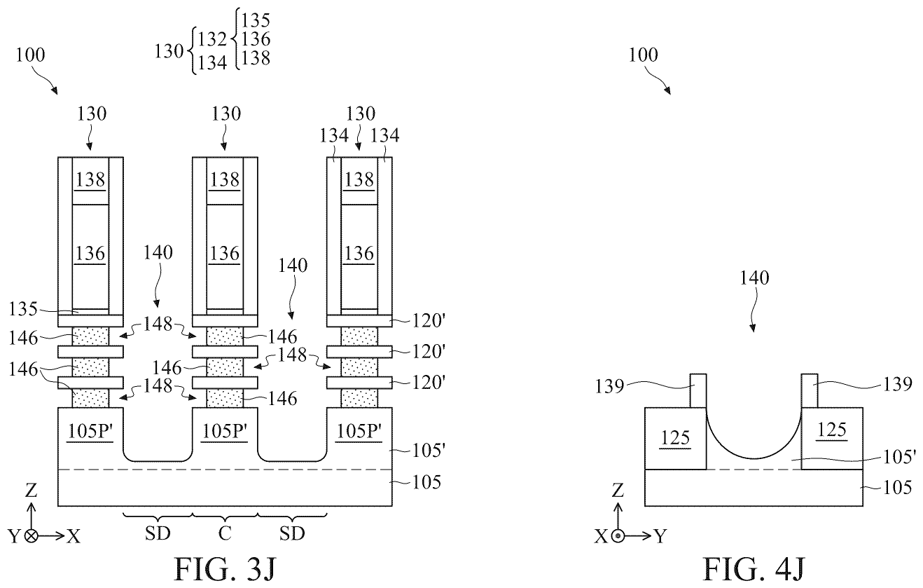

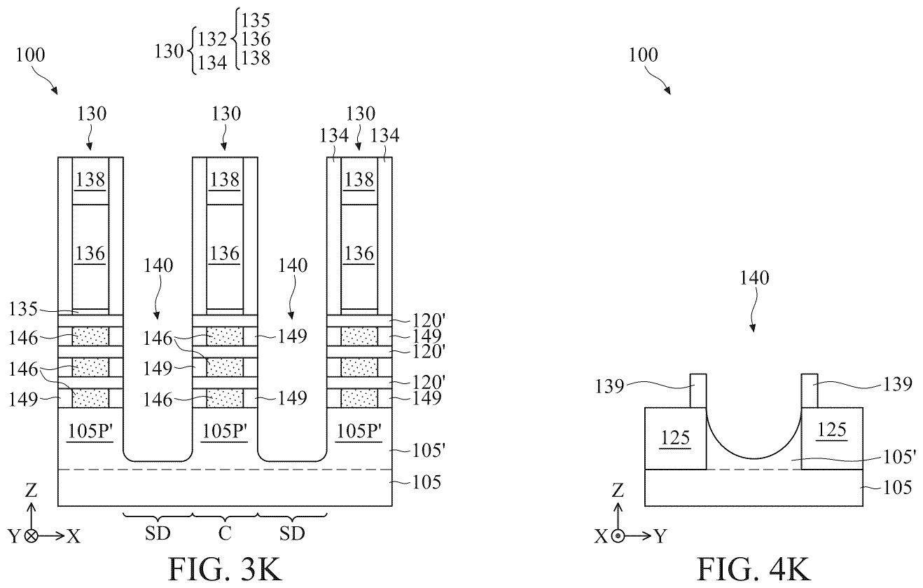

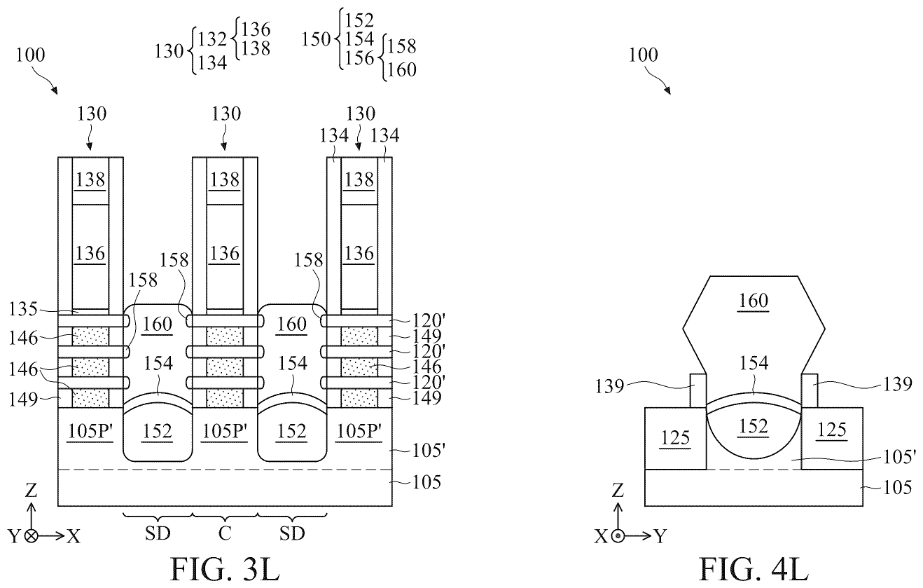

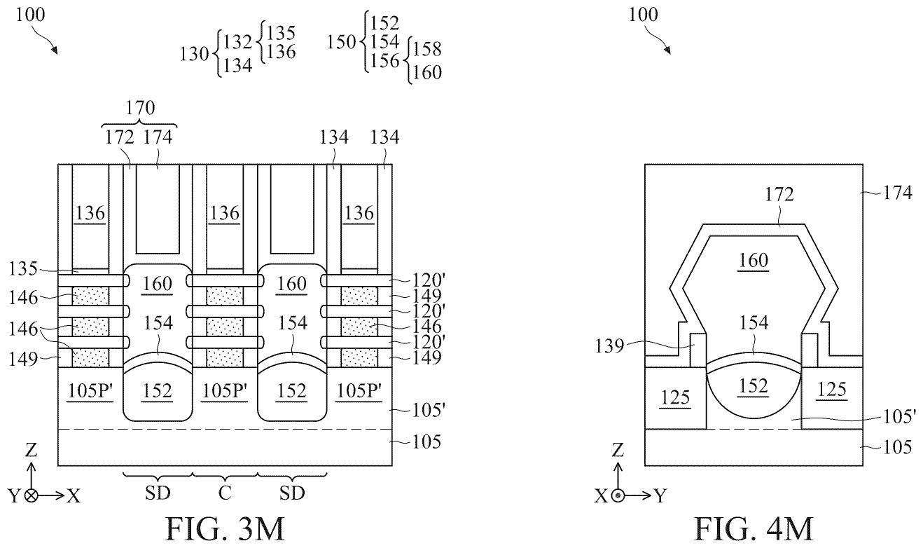

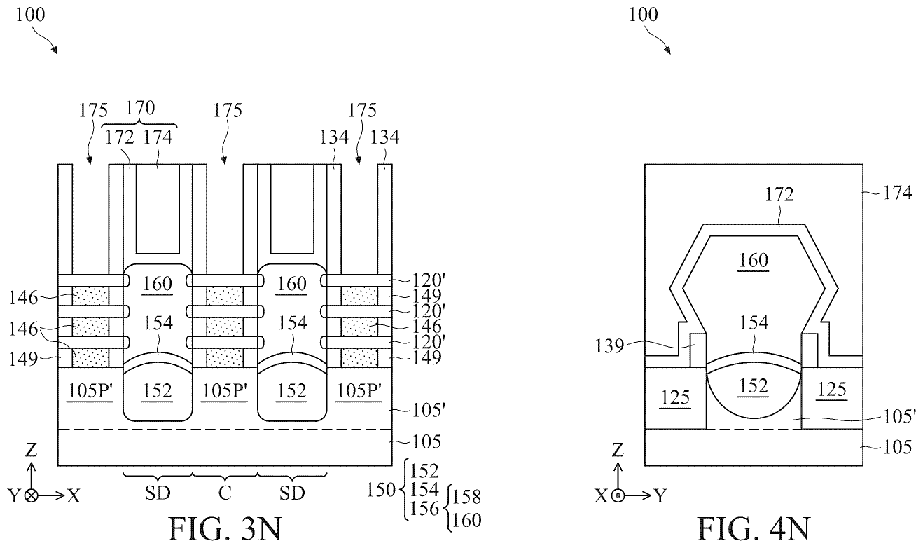

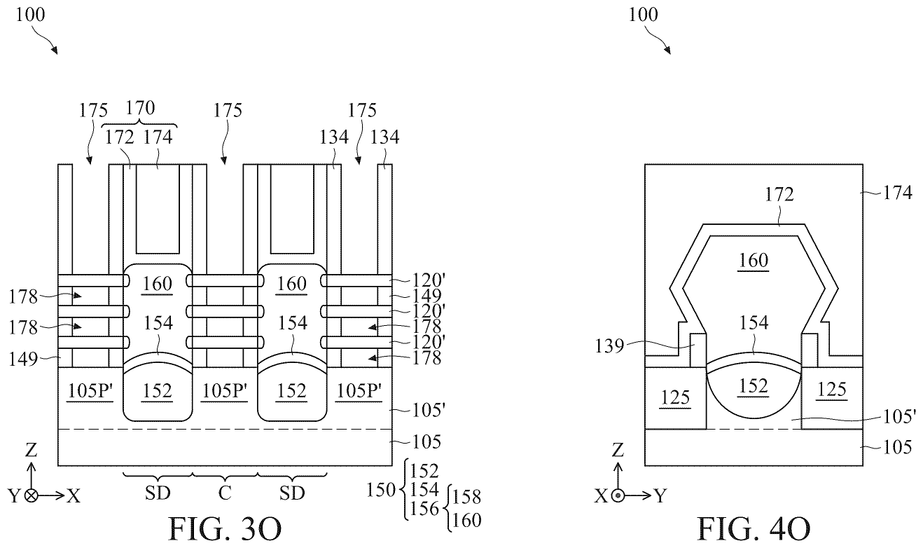

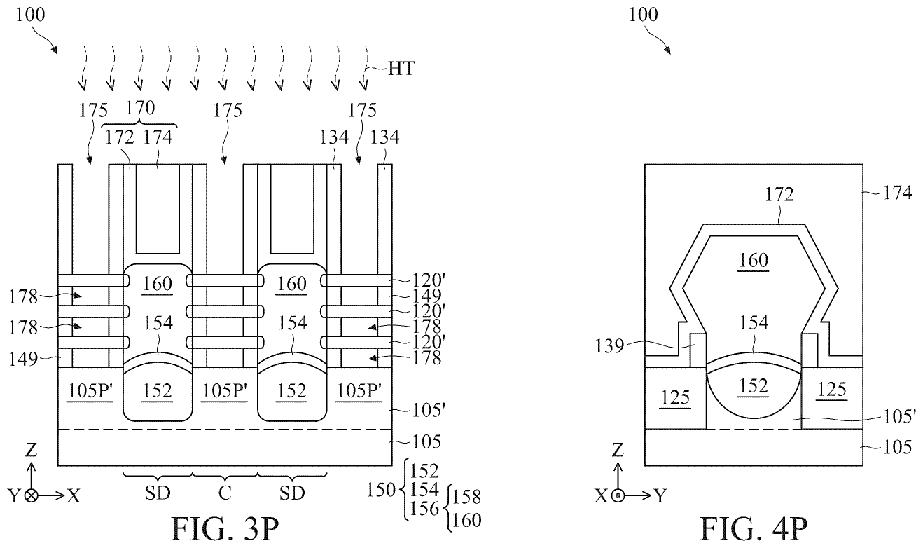

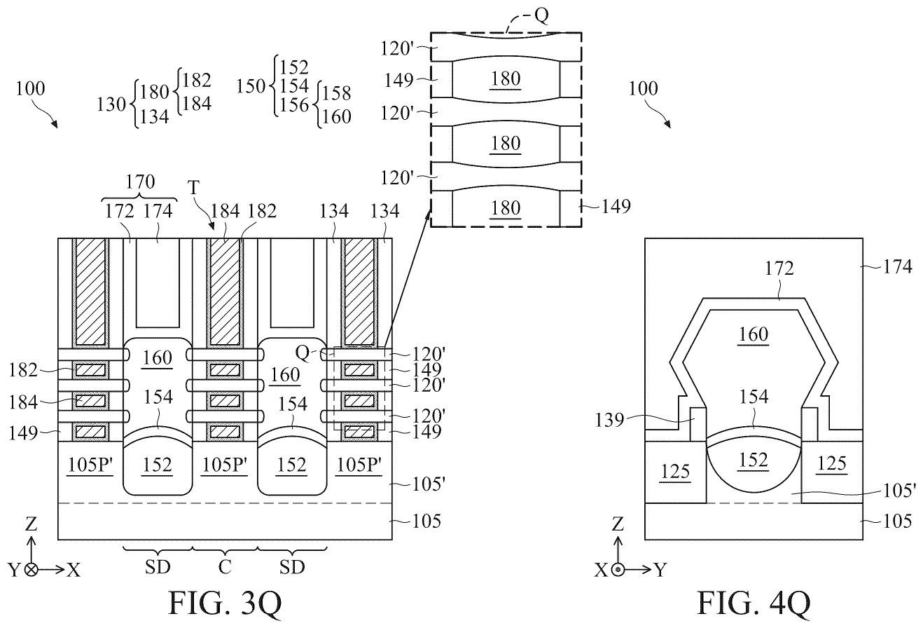

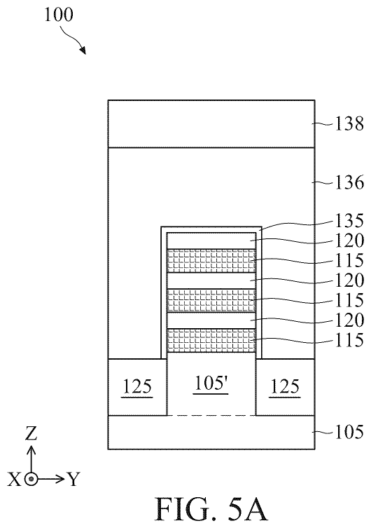

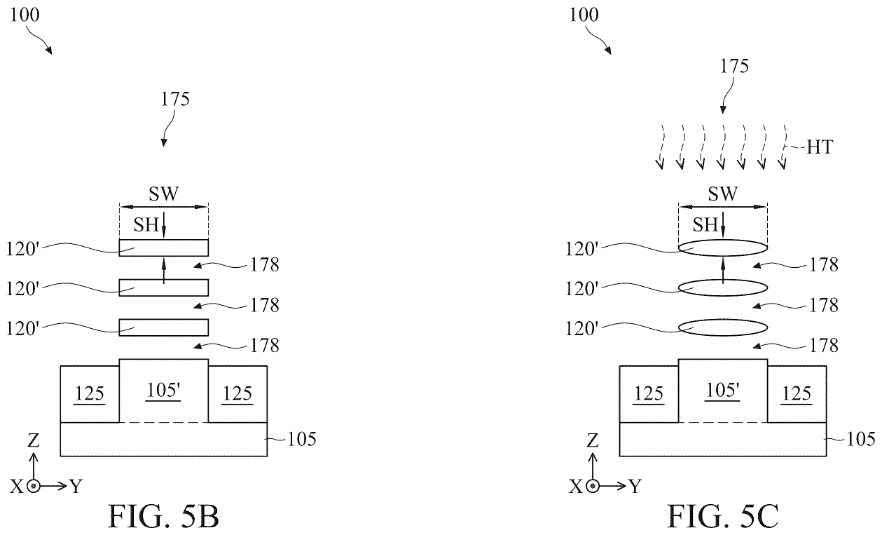

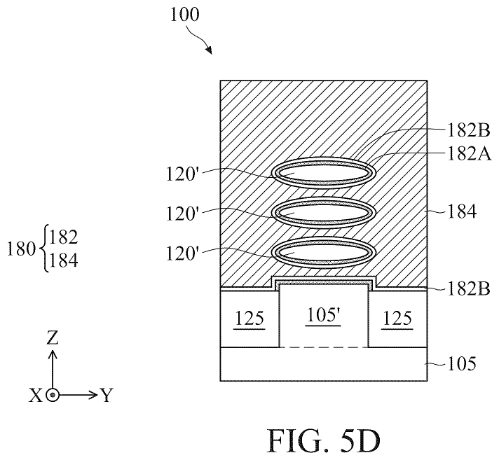

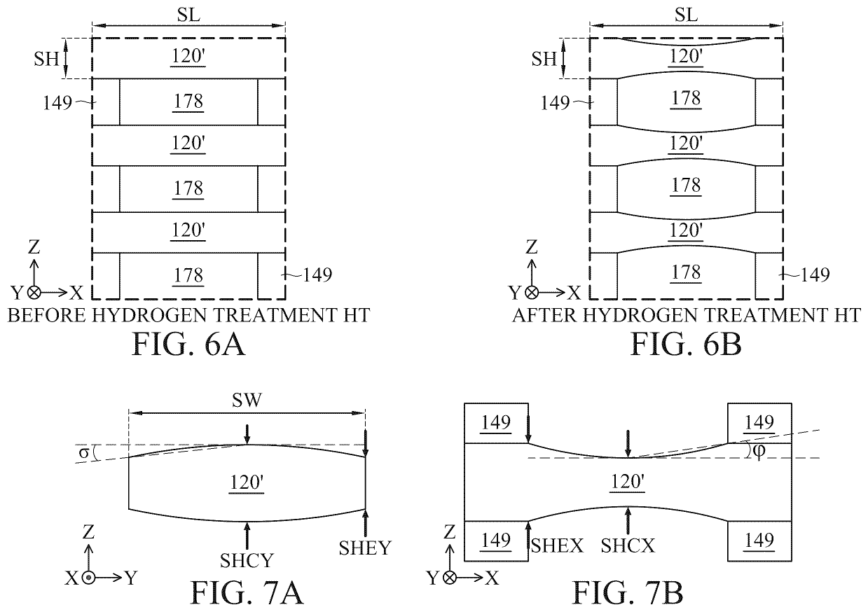

FIG. 2 is a top view of a device 100, in portion or entirety, that may be processed by method 10 of FIG. 1, according to various aspects of the present disclosure. FIGS. 3A-3Q are cross-sectional views of device 100, in portion or entirety, along line A-A of FIG. 2 at various stages of fabrication (such as those associated with method 10 of FIG. 1) according to various aspects of the present disclosure. FIGS. 4A-4Q are cross-sectional views of device 100, in portion or entirety, along line B-B of FIG. 2 at various stages of fabrication (such as those associated with method 10 of FIG. 1) according to various aspects of the present disclosure. FIGS. 4A-4Q correspond with the stages of fabrication of FIGS. 3A-3Q, respectively. FIGS. 5A-5D are cross-sectional views of device 100, in portion or entirety, along line C-C of FIG. 2 at various stages of fabrication (such as those associated with method 10 of FIG. 1) according to various aspects of the present disclosure. FIG. 5A corresponds with the stage of fabrication of FIG. 3D and FIG. 4D, FIG. 5B corresponds with the stage of fabrication of FIG. 3O and FIG. 4O, FIG. 5C corresponds with the stage of fabrication of FIG. 3P and FIG. 4P, and FIG. 5D corresponds with the stage of fabrication of FIG. 3Q and FIG. 4Q. FIG. 6A is a diagrammatic cross-sectional view of a channel region, in portion or entirety, of the device of FIG. 3O, according to various aspects of the present disclosure. FIG. 6B is a diagrammatic cross-sectional view of a channel region, in portion or entirety, of the device of FIG. 3P, according to various aspects of the present disclosure. FIG. 7A is a diagrammatic cross-sectional view of a channel region, in portion or entirety, of the device of FIG. 5C, according to various aspects of the present disclosure. FIG. 7B is a diagrammatic cross-sectional view of a channel region, in portion or entirety, of the device of FIG. 3P, according to various aspects of the present disclosure. FIG. 2, FIGS. 3A-3Q, FIGS. 4A-4Q, FIGS. 5A-5D, FIG. 6A, FIG. 6B, FIG. 7A, and FIG. 7B are discussed concurrently herein for ease of description and understanding. FIG. 2, FIGS. 3A-3Q, FIGS. 4A-4Q, FIGS. 5A-5D, FIG. 6A, FIG. 6B, FIG. 7A, and FIG. 7B have been simplified for the sake of clarity to better understand the inventive concepts of the present disclosure. Additional features may be added in device 100, and some of the features described below may be replaced, modified, or eliminated in other embodiments of device 100.

After undergoing processing associated with FIG. 2, FIGS. 3A-3Q, FIGS. 4A-4Q, and FIGS. 5A-5D, device 100 may include at least one GAA transistor (i.e., a transistor having a gate that at least partially surrounds a suspended channel(s) (for example, a nanowire(s), a nanosheet(s), a nanobar(s), or the like) that extends between source/drains). In some embodiments, device 100 is processed to form a p-type transistor. In some embodiments, device 100 is processed to form an n-type transistor. In some embodiments, device 100 is processed to form an n-type transistor and a p-type transistor. In such embodiments, device 100 may include a complementary metal-oxide semiconductor (CMOS) transistor. Device 100 may be included in a microprocessor, a memory, other IC device, or combinations thereof. In some embodiments, device 100 is a portion of an IC chip, a system on chip (SoC), or portion thereof, and device 100 may include various passive electronic devices and/or active electronic devices, such as resistors, capacitors, inductors, diodes, p-type field effect transistors (PFETs), n-type FETs (NFETs), metal-oxide-semiconductor FETs (MOSFETs), CMOS transistors, bipolar junction transistors (BJTs), laterally diffused MOS (LDMOS) transistors, high voltage transistors, high frequency transistors, other suitable components, or combinations thereof.

Referring to FIG. 2, FIG. 3A, FIG. 4A, FIG. 3B, and FIG. 4B, fabrication of device 100 may include forming and/or receiving a device precursor, which may include a substrate 105 and a multilayer stack 110. Multilayer stack 110 may include sacrificial semiconductor layers 115 and semiconductor layers 120, and multilayer stack 110 may be disposed over a base layer 105′, which may be and/or form a portion of substrate 105, such as a protrusion, an extension, and/or a mesa thereof. Multilayer stack 110 may correspond with and/or define an active region 122 of device 100. Active region 122 extends lengthwise along an x-direction (i.e., length is along the x-direction, width is along a y-direction, and height is along a z-direction), and active region 122 may be oriented substantially parallel to other active regions. Active region 122 may include channel regions (C), source regions, and drain regions. The source regions and the drain regions may collectively be referred to as source/drain regions (S/D).

Substrate 105 includes an elementary semiconductor, such as silicon and/or germanium; a compound semiconductor, such as silicon carbide, gallium arsenide, gallium phosphide, indium phosphide, indium arsenide, indium antimonide, or combinations thereof; an alloy semiconductor, such as SiGe, GaAsP, AlInAs, AlGaAs, GaInAs, GaInP, GaInAsP, or combinations thereof; or combinations thereof. In some embodiments, substrate 105 is a silicon substrate. In some embodiments, substrate 105 is a semiconductor-on-insulator substrate, such as a silicon-on-insulator (SOI) substrate, a silicon germanium-on-insulator (SGOI) substrate, or a germanium-on-insulator (GOI) substrate. Substrate 105 (and base layer 105′) may include various doped regions, such as p-type doped regions (e.g., p-wells), n-type doped regions (e.g., n-wells), or combinations thereof. N-type doped regions include n-type dopants, such as phosphorus, arsenic, other n-type dopant, or combinations thereof. P-type doped regions include p-type dopants, such as boron, indium, gallium, other p-type dopant, or combinations thereof. In some embodiments, the doped regions include p-type dopants and n-type dopants.

In some embodiments, multilayer stack 110 is formed by depositing sacrificial semiconductor layers 115 and semiconductor layers 120 over substrate 105 (see, e.g., FIG. 3A and FIG. 4A) and patterning sacrificial semiconductor layers 115 and semiconductor layers 120 (see, e.g., FIG. 3B and FIG. 4B). In some embodiments, the patterning is extended to substrate 105, thereby forming base layer 105′ (also referred to as an extension) thereof. Sacrificial semiconductor layers 115 and semiconductor layers 120 are stacked vertically (e.g., along the z-direction) in an interleaving and/or alternating configuration from a top of substrate 105. In some embodiments, the depositing includes epitaxially growing sacrificial semiconductor layers 115 and semiconductor layers 120 in the depicted interleaving/alternating configuration. For example, a first one of sacrificial semiconductor layers 115 is epitaxially grown on substrate 105, a first one of semiconductor layers 120 is epitaxially grown on the first one of sacrificial semiconductor layers 115, a second one of sacrificial semiconductor layers 115 is epitaxially grown on the first one of semiconductor layers 120, and so on until multilayer stack 110 has a desired number of sacrificial semiconductor layers 115 and semiconductor layers 120. In such embodiments, sacrificial semiconductor layers 115 and semiconductor layers 120 may be referred to as epitaxial layers. In some embodiments, epitaxial growth of sacrificial semiconductor layers 115 and semiconductor layers 120 is achieved by a molecular beam epitaxy (MBE) process, a chemical vapor deposition (CVD) process, a metalorganic CVD (MOCVD) process, other suitable epitaxial growth process, or combinations thereof.

A composition of sacrificial semiconductor layers 115 is different than a composition of semiconductor layers 120 to achieve etch selectivity. For example, sacrificial semiconductor layers 115 and semiconductor layers 120 include different materials, constituent atomic percentages, constituent weight percentages, other characteristics, or combinations thereof to achieve etch selectivity. In some embodiments, sacrificial semiconductor layers 115 include silicon germanium, semiconductor layers 120 include silicon, and an etch rate of semiconductor layers 120 is different than an etch rate of sacrificial semiconductor layers 115 to a given etchant. In some embodiments, sacrificial semiconductor layers 115 and semiconductor layers 120 include the same material but with different constituent atomic percentages. For example, sacrificial semiconductor layers 115 and semiconductor layers 120 may include silicon germanium, and sacrificial semiconductor layers 115 and semiconductor layers 120 may have different germanium atomic percentages to provide etch selectivity. Sacrificial semiconductor layers 115 and semiconductor layers 120 may include any combination of materials that provides desired etching selectivity, desired oxidation rate differences, desired performance characteristics (e.g., materials that maximize current flow), or combinations thereof.

Semiconductor layers 120 or portions thereof may form channels of transistors. In the depicted embodiment, multilayer stack 110 includes three sacrificial semiconductor layers 115 and three semiconductor layers 120. Multilayer stack 110 thus includes three semiconductor layer pairs disposed over substrate 105, each of which has a respective sacrificial semiconductor layer 115 and a respective semiconductor layer 120. After processing of multilayer stack 110, this configuration may result in transistors having three channels. In some embodiments, multilayer stack 110 includes different numbers of semiconductor layers 120 depending, for example, on a number of channels desired for the transistors. For example, multilayer stack 110 may include two to six semiconductor layer pairs, each of which may include a respective sacrificial semiconductor layer 115 and a respective semiconductor layer 120.

After patterning, multilayer stack 110 may include a semiconductor layer stack (i.e., sacrificial semiconductor layers 115 and semiconductor layers 120) disposed over base layer 105′ (also referred to as a substrate extension, a substrate fin portion, a fin portion, a protrusion, an etched substrate portion, etc.). Multilayer stack 110 may be referred to as a fin, a fin structure, a fin element, an active fin region, an active region, etc. In some embodiments, base layer 105′ may be considered a portion of multilayer stack 110. Multilayer stack 110 extends substantially along an x-direction, having a length along the x-direction, a width along a y-direction, and a height along a z-direction. In some embodiments, a lithography process and/or an etching process is performed to pattern sacrificial semiconductor layers 115, semiconductor layers 120, and substrate 105 to form multilayer stack 110. In some embodiments, multilayer stack 110 is formed by a multiple patterning process, such as a double patterning lithography (DPL) process (for example, a lithography-etch-lithography-etch (LELE) process, a self-aligned double patterning (SADP) process, a spacer-is-dielectric (SID) process, other double patterning process, or combinations thereof), a triple patterning process (for example, a lithography-etch-lithography-etch-lithography-etch (LELELE) process, a self-aligned triple patterning (SATP) process, other triple patterning process, or combinations thereof), other multiple patterning process (for example, self-aligned quadruple patterning (SAQP) process), or combinations thereof. In some embodiments, directed self-assembly (DSA) techniques are implemented. In some embodiments, multilayer stack 110 is formed by a fin fabrication process.

Referring to FIG. 2, FIG. 3C, and FIG. 4C, isolation structures 125 may be formed adjacent to and around a lower portion of multilayer stack 110 (e.g., base layer 105′ thereof), and multilayer stack 110 may be separated from other multilayer stacks and/or other device regions by isolation structures 125. Isolation structures 125 may electrically isolate an active device region (e.g., multilayer stack 110) from other device regions, such as other multilayer stacks. Isolation structures 125 include silicon oxide, silicon nitride, silicon oxynitride, other suitable isolation material (including, silicon, oxygen, nitrogen, carbon, other suitable isolation constituent, or combinations thereof), or combinations thereof. Isolation structures 125 may have a multilayer structure. For example, isolation structures 125 may include a bulk dielectric (e.g., an oxide layer) over a dielectric liner (e.g., silicon nitride, silicon oxide, silicon oxynitride, silicon oxycarbonitride, or combinations thereof). In some embodiments, the dielectric liner is a doped dielectric liner, such as a boron silicate glass (BSG) liner and/or a phosphosilicate glass (PSG) liner. Dimensions and/or characteristics of isolation structures 125 (also referred to as substrate isolation structures, in some embodiments) may be configured to provide shallow trench isolation (STI) structures, deep trench isolation (DTI) structures, local oxidation of silicon (LOCOS) structures, other suitable isolation structures, or combinations thereof.

In some embodiments, isolation structures 125 are formed by depositing one or more isolation liners (e.g., a dielectric liner and/or a semiconductor liner) over device 100 that partially fills trenches, depositing an isolation bulk material (e.g., oxide) over device 100 that fills remainders of the trenches, performing a planarization process, and recessing (e.g., etching back) the isolation liner(s) and isolation bulk material. The planarization process, such as a chemical mechanical polishing (CMP) process, may be performed until reaching and exposing a planarization stop layer, such as a mask layer over multilayer stack 110 (which may have been used to pattern semiconductor layers 120 and sacrificial semiconductor layers 115) and/or one of semiconductor layers 120 of multilayer stack 110 (e.g., a topmost one thereof). Remainders of the isolation liner(s) and the isolation bulk material may form isolation liners (e.g., dielectric liners) and isolation bulk layers (e.g., oxide layers), respectively, of isolation structures 125. The planarization process may partially or completely remove the mask layer. The isolation liner(s) are formed by atomic layer deposition (ALD), CVD, physical vapor deposition (PVD), high density plasma CVD (HDPCVD), MOCVD, RPCVD, PECVD, LPCVD, atomic layer CVD (ALCVD), atmospheric pressure CVD (APCVD), sub-atmospheric CVD (SACVD), or combinations thereof. In some embodiments, isolation bulk material (e.g., oxide) is formed by flowable CVD (FCVD), a high aspect ratio deposition (HARP) process, HDPCVD, or combinations thereof. In some embodiments, an annealing process is performed before and/or after the planarization process to cure and/or densify isolation bulk material.

Referring to FIG. 2, FIG. 3D, FIG. 4D, FIG. 5A, FIG. 3E, and FIG. 4E, gate structures 130 may be formed over channel regions (C) of active region 122 and between respective source/drain regions (S/D) of active region 122. One or more gate structures 130 may include a respective dummy gate stack 132 and respective gate spacers 134. Dummy gate stacks 132 extend lengthwise along a direction different than (e.g., orthogonal to) the lengthwise direction of multilayer stack 110. For example, dummy gate stacks 132 extend along the y-direction, having a length along the y-direction, a width along the x-direction, and a height along the z-direction. Dummy gate stacks 132 may extend substantially parallel to one another. Referring to FIG. 3D (e.g., along the gate widthwise direction), dummy gate stacks 132 are disposed on top of respective channel regions, and dummy gate stacks 132 are disposed between respective source/drain regions. Referring to FIG. 5A (e.g., along the gate lengthwise direction), dummy gate stacks 132 may wrap respective channel regions (e.g., be disposed over the top and sidewalls thereof), and dummy gate stacks 132 may be disposed over tops of isolation structures 125. Each dummy gate stack 132 may include a dummy gate dielectric 135, a dummy gate bulk 136, and a hard mask 138. Dummy gate dielectric 135 includes a dielectric material, such as silicon oxide and/or other suitable dielectric material. Dummy gate bulk 136 includes a suitable placeholder/sacrificial material, such as polysilicon. In some embodiments, forming dummy gate stacks 132 includes depositing a dummy gate dielectric layer(s) over multilayer stack 110, depositing a polysilicon layer(s) over the dummy gate dielectric layer, and depositing a hard mask layer(s) over the polysilicon layer. One or more lithography and etching processes may then be performed to pattern the hard mask layer, the polysilicon layer, and the dummy gate dielectric layer, and remainders of the hard mask layer, the polysilicon layer, and the dummy gate dielectric layer may form dummy gate dielectrics 135, dummy gate bulks 136, and hard masks 138, respectively, of dummy gate stacks 132, such as depicted.

Referring to FIG. 3E and FIG. 4E, gate spacers 134 are formed adjacent to and along sidewalls of dummy gate stacks 132. In some embodiments, fin spacers 139 may be formed over isolation structures 125 and adjacent to (e.g., along sidewalls) of multilayer stack 110 in source/drain regions, such as depicted in FIG. 4E. Gate spacers 134 and fin spacers 139 may be formed by any suitable process, and in some embodiments, gate spacers 134 and fin spacers 139 are formed simultaneously. Gate spacers 134 and fin spacers 139 include a dielectric material, which may include silicon, oxygen, carbon, nitrogen, other suitable dielectric constituent, or combinations thereof (e.g., silicon oxide, silicon nitride, silicon oxynitride, silicon carbide, silicon carbonitride, silicon oxycarbide, silicon oxycarbonitride, or combinations thereof). In some embodiments, gate spacers 134 have a multilayer structure, such as two or more dielectric layers having different compositions. In some embodiments, gate spacers 134 include more than one set of spacers, such as seal spacers, offset spacers, sacrificial spacers, dummy spacers, main spacers, or combinations thereof. In such embodiments, the various sets of spacers may have different compositions. In some embodiments, fin spacers 139 have a multilayer structure.

Referring to FIG. 3F and FIG. 4F, a source/drain etch removes portions of multilayer stack 110 that are not covered by gate structures 130, thereby forming source/drain recesses (trenches) 140. For example, the source/drain etch removes semiconductor layers 120 and sacrificial semiconductor layers 115 in source/drain regions, thereby exposing base layer 105′. The source/drain etch may further remove some, but not all, of base layer 105′ in source/drain regions, such that source/drain recesses 140 extend into but not through base layer 105′. After the source/drain etch, sacrificial semiconductor layers 115, semiconductor layers 120, and projecting portions of base layer 105′ (also be referred to as base protrusions 105P′ hereafter) may remain in channel regions, and source/drain recesses 140 expose sidewalls of portions of sacrificial semiconductor layers 115, semiconductor layers 120, and base protrusions 105P′ remaining in channel regions. The source/drain etch is a dry etch, a wet etch, other suitable etch, or combinations thereof. In some embodiments, the source/drain etch is a multistep etch process, which may alternate etchants to separately and alternately remove sacrificial semiconductor layers 115 and semiconductor layers 120. In some embodiments, source/drain etch parameters (e.g., etchant thereof) are tuned to selectively remove semiconductor materials (e.g., semiconductor layers 120, sacrificial semiconductor layers 115, and base layer 105′) with negligible (to no) removal of dielectric materials and/or other materials (e.g., dummy gate stacks 132, gate spacers 134, fin spacers 139, isolation structures 125, etc.).

Referring to FIGS. 3G-3I and FIGS. 4G-4I, sacrificial semiconductor layers 115 are replaced with sacrificial oxide layers 146, in some embodiments. The present disclosure contemplates omitting replacement of sacrificial semiconductor layers 115 with sacrificial oxide layers 146, such as described further herein. Referring to FIG. 3G and FIG. 4G, an etching process selectively removes sacrificial semiconductor layers 115 exposed by source/drain recesses 140, thereby forming gaps 144 in channel regions. The etching process may selectively remove sacrificial semiconductor layers 115 with respect to substrate 105, semiconductor layers 120, dummy gate stacks 132 (e.g., hard masks 138 thereof), gate spacers 134, fin spacers 139, or combinations thereof. In other words, the etching process removes sacrificial semiconductor layers 115 with negligible (to no) removal of substrate 105, semiconductor layers 120, dummy gate stacks 132 (e.g., hard masks 138 thereof), gate spacers 134, fin spacers 139, or combinations thereof. In some embodiments, an etchant is selected for the etching process that etches silicon germanium (e.g., sacrificial semiconductor layers 115) at a higher rate than silicon (e.g., semiconductor layers 120 and base layer 105′) and dielectric materials (e.g., gate spacers 134, fin spacers 139, hard masks 138, and the like). The etching process is a dry etch, a wet etch, other suitable etch, or combinations thereof. In some embodiments, before the etching process, an oxidation process may be performed to convert sacrificial semiconductor layers 115 into semiconductor oxide layers (e.g., silicon germanium oxide layers). In such embodiments, the etching process removes semiconductor oxide layers to form gaps 144.

Semiconductor layers 120 remaining in channel regions are suspended over base protrusions 105P′ after removing sacrificial semiconductor layers 115. In the depicted embodiment, each channel region has three suspended semiconductor layers 120, which may be referred to hereafter as channel layers 120′. Channel layers 120′ are vertically stacked along the z-direction, and channel layers 120′ may provide three channels through which current can flow between respective, subsequently formed source/drains. In some embodiments, after removing sacrificial semiconductor layers 115, an etching process may be performed to modify a profile of channel layers 120′ to provide target dimensions and/or target shapes thereof. For example, the etching process may provide channel layers 120′ with cylindrical-shaped profiles (e.g., nanowires), rectangular-shaped profiles (e.g., nanobars), sheet-shaped profiles (e.g., nanosheets), or any other suitable shaped profile. In some embodiments, channel layers 120′ have nanometer-sized dimensions and may be referred to as “nanostructures.” In some embodiments, channel layers 120′ have sub-nanometer dimensions and/or other suitable dimensions.

Referring to FIG. 3H (and FIG. 4H) and FIG. 3I (and FIG. 4I), sacrificial oxide layers 146 are formed in gaps 144. Sacrificial oxide layers 146 include oxygen and silicon, carbon, nitrogen, other suitable constituent, or combinations thereof. For example, sacrificial oxide layers 146 include oxygen and silicon, and sacrificial oxide layers 146 may be silicon oxide layers. In some embodiments, sacrificial oxide layers 146 are formed by depositing an oxide layer 146′ over device 100 (e.g., FIG. 3H and FIG. 4H) and etching oxide layer 146′, such that oxide layer 146′ is removed from source/drain regions, but not channel regions, of device 100 (e.g., FIG. 3I and FIG. 4I). Referring to FIG. 3H and FIG. 4H, as-deposited oxide layer 146′ fills gaps 144, partially fills source/drain recesses 140, and lines source/drain recesses 140. As-deposited oxide layer 146′ may further be disposed over gate structures 130, isolation structures 125, fin spacers 139, other features, or combinations thereof. Oxide layer 146′ is formed by FCVD, ALD, PECVD, other process, or combinations thereof. In some embodiments, sacrificial oxide layers 146 have multilayer structures, such as a first oxide layer and a second oxide layer. The first oxide layer and the second oxide layer may be formed of a same material (e.g., silicon oxide), but formed by different deposition processes. For example, the first oxide layer may be formed by ALD, and the second oxide layer may be formed over the first oxide layer by FCVD. In some embodiments, the first oxide layer and the second oxide layer are formed of different oxide materials by the same type, or different types, of deposition processes.

Referring to FIG. 3I and FIG. 4I, an etching process removes exposed portions of oxide layer 146′ (e.g., those not filling gaps 144). For example, the etching process may remove portions of oxide layer 146′ disposed on sidewalls of channel layers 120′, sidewalls of base protrusions 105P′, surfaces of base layer 105′ that form bottoms of source/drain recesses 140, tops and sidewalls of fin spacers 139, tops and sidewalls of gate spacers 134, tops of dummy gate stacks 132, and tops of isolation structures 125. Remainders of oxide layer 146′ (e.g., filling gaps 144) provide sacrificial oxide layers 146 in the channel regions. The etching process may selectively remove oxide layer 146′ with respect to substrate 105, channel layers 120′, dummy gate stacks 132 (e.g., hard masks 138), gate spacers 134, fin spacers 139, isolation structures 125, or combinations thereof. In other words, the etching process removes oxide layer 146′ with negligible (to no) removal of substrate 105, channel layers 120′, hard masks 138, gate spacers 134, fin spacers 139, isolation structures 125, or combinations thereof. In some embodiments, an etchant is selected that etches an oxide material (e.g., oxide layer 146′) at a higher rate than silicon (e.g., channel layers 120′ and base layer 105′), dielectric materials different than the oxide material (e.g., gate spacers 134, fin spacers 139, hard masks 138, etc.). The etching process is a dry etch, a wet etch, other suitable etch, or combinations thereof.

Referring to FIG. 3J and FIG. 4J, an etching process (e.g., an anisotropic etch) laterally recesses sacrificial oxide layers 146 to form notches 148 under gate structures 130 (e.g., under gate spacers 134 thereof). For example, the etching process may laterally etch (e.g., along the x-direction and/or the y-direction) sacrificial oxide layers 146 to reduce their lengths along the x-direction, such that lengths of sacrificial oxide layers 146 are less than lengths of channel layers 120′. Sacrificial oxide layers 146 may be removed from ends of channel layers 120′, thereby exposing tops and bottoms of ends of channel layers 120′. In some embodiments, notches 148 laterally extend (e.g., along the x-direction) under dummy gate stacks 132. In some embodiments, the etching process may recess isolation structures 125, which may provide isolation structures 125 with curved (e.g., concave) top surfaces.

Referring to FIG. 3K and FIG. 4K, inner spacers 149 are formed in notches 148, and remainders of sacrificial oxide layers 146 are disposed between respective inner spacers 149. Inner spacers 149 may replace ends of sacrificial oxide layers 146. Inner spacers 149 are disposed under gate spacers 134 along sidewalls of sacrificial oxide layers 146. Further, inner spacers 149 are disposed between ends of respective semiconductor layers 120, and bottom inner spacers 149 are disposed between ends of respective bottom semiconductor layers 120 and respective protrusions 105P′. Forming inner spacers 149 may include an inner spacer deposition and an inner spacer etch. The inner spacer deposition may form an inner spacer layer over device 100 that at least partially fills notches 148. In some embodiments, a single deposition process is performed to form an inner spacer layer that fills notches 148. In some embodiments, inner spacers 149 have multilayer structures, and the inner spacer deposition includes more than one deposition process to form a multilayer inner spacer, such as a first deposition process to form a first inner spacer sublayer and a second deposition process to form a second inner spacer sublayer. The first inner spacer sublayer partially fills notches 148, and the second inner spacer sublayer may partially or completely fill notches 148. Composition of the first inner spacer sublayer is the same or different than composition of the second inner spacer sublayer.

The inner spacer etch may selectively etch the inner spacer layer with negligible (to no) etching of channel layers 120′, base protrusions 105P′, dummy gate stacks 132 (e.g., hard masks 138 thereof), gate spacers 134, fin spacers 139, isolation structures 125, or combinations thereof. Remainders of the inner spacer layer provide inner spacers 149, such as depicted. To achieve desired etching selectivity, the inner spacer layer (and thus inner spacers 149) have a composition different than compositions of channel layers 120′, protrusions 105P′, dummy gate stacks 132, gate spacers 134, fin spacers 139, isolation structures 125, or combinations thereof. In some embodiments, the inner spacer layer includes a dielectric material that includes silicon, oxygen, carbon, nitrogen, other suitable constituent, or combinations thereof. For example, the inner spacer layer may be a silicon carbide layer, a silicon carbonitride layer, a silicon oxycarbonitride layer, a silicon oxycarbide layer, or combinations thereof. The inner spacer etch is a dry etch, a wet etch, other suitable etch, or combinations thereof. In some embodiments, parameters of the inner spacer deposition and/or the inner spacer etch are configured and/or tuned to provide inner spacers 149 with air gaps. Notably, the formation of inner spacers 149, including respective manufacturing steps described above (e.g., with reference to FIG. 3J, FIG. 4J, FIG. 3K, and FIG. 4K), may be optional. That is, the formation of inner spacers 149 may be omitted, and device 100 may not include inner spacers 149 (i.e., inner spacers may not exist in a final device/semiconductor structure), in some embodiments.

Referring to FIG. 3L and FIG. 4L, source/drain structures 150 are formed in source/drain recesses 140. One or more source/drain structures 150 may include an undoped semiconductor layer 152, an insulator layer 154, and a doped semiconductor layer 156. In some embodiments, doped semiconductor layers 156 have a multilayer structure, such as a respective doped semiconductor layer 158 and a respective doped semiconductor layer 160. In some embodiments, source/drain structures 150 form source/drains of p-type transistors, and source/drain structures 150 may include semiconductor material(s) doped with p-type dopant (e.g., boron, gallium, other p-type dopant, or combinations thereof). In some embodiments, source/drain structures 150 form source/drains of n-type transistors, and source/drain structures 150 may include semiconductor material(s) doped with n-type dopant (e.g., carbon, phosphorous, arsenic, antimony, other n-type dopant, or combinations thereof). The present disclosure contemplates various configurations of source/drain structures 150. For example, undoped semiconductor layer 152 and/or insulator layer 154 may be omitted from source/drain structures 150. In some embodiments, source/drain structures 150 may have different configurations. As used herein, source/drain, source/drain region, source/drain structure, source/drain feature, epitaxial source/drain, epitaxial source/drain feature, etc. may refer to a source of device 100, a drain of device 100, or a source and/or a drain of multiple devices (including device 100).

Undoped semiconductor layers 152 may be formed in bottoms of source/drain recesses 140. In the depicted embodiment, undoped semiconductor layers 152 are disposed below bottommost channel layers 120′, and undoped semiconductor layers 152 may extend slightly above top surfaces of protrusions 105P′. In some embodiments, top surfaces of undoped semiconductor layers 152 are substantially level with or below top surfaces of protrusions 105P′ (i.e., they may not extend beyond top surfaces of protrusions 105P′). Undoped semiconductor layers 152 are dopant-free (i.e., substantially free of n-type dopants and p-type dopants). For example, no intentional doping is performed when forming undoped semiconductor layers 152. Undoped semiconductor layers 152 may provide high resistance paths at bottoms of source/drains, which may suppress leakage current into substrate 105/protrusions 105P′. Undoped semiconductor layers 152 include silicon, germanium, silicon germanium, other suitable semiconductor materials, or combinations thereof. In some embodiments, undoped semiconductor layers 152 are dopant-free silicon germanium layers, dopant-free silicon layers, or combinations thereof. In some embodiments, semiconductor materials having dopant concentrations less than about 5×10¹⁸ cm⁻³, such as about 1×10¹⁸ cm⁻³ to about 5×10¹⁸ cm⁻³, may be considered undoped and/or unintentionally doped (UID).

Undoped semiconductor layers 152 may be deposited on and/or grown from substrate 105, base layer 105′, protrusions 105P′, or combinations thereof. In some embodiments, undoped semiconductor layers 152 are formed by a selective epitaxial growth (SEG) process, which may selectively deposit/grow semiconductor material on/from exposed semiconductor surfaces. Undoped semiconductor layers 152 may thus be referred to as undoped epitaxial layers. The SEG process may use CVD techniques (e.g., vapor-phase epitaxy (VPE), ultra-high vacuum CVD (UHV-CVD), low pressure CVD (LPCVD), PECVD, or the like), molecular beam epitaxy, other suitable epitaxial growth process, or combinations thereof. In some embodiments, undoped semiconductor layers 152 are formed by a bottom-up deposition process. For example, semiconductor material may be deposited/grown on protrusions 105P′, base layer 105′, and/or substrate 105 (i.e., in bottoms of source/drain recesses 140) with minimal (to no) deposition/growth of semiconductor material on channel layers 120′. In some embodiments, a post-deposition etch may be performed after the bottom-up deposition process to remove any semiconductor material that may have formed on channel layers 120′. The post-deposition etch may be a dry etch, a wet etch, other suitable etch, or combinations thereof.

Insulator layers 154 may be formed in source/drain recesses 140 over undoped semiconductor layers 152. Insulator layers 154 partially fill source/drain recesses 140, and insulator layers 154 are disposed below bottommost channel layers 120′ (e.g., below bottoms thereof). Insulator layers 154 may be disposed on bottommost inner spacers 149 and/or protrusions 105P′. Insulator layers 154 include an electrically insulating material, such as a dielectric material, that may reduce unwanted leakage current, such as current that may undesirably flow between doped semiconductor layers 156 through protrusions 105P′. In some embodiments, insulator layers 154 include a silicon-comprising dielectric material, such as silicon nitride, silicon oxynitride, silicon oxycarbonitride, silicon oxycarbide, silicon carbonitride, other silicon-comprising dielectric material (which may include silicon and nitrogen, carbon, oxygen, other suitable dielectric constituent, or combinations thereof), or combinations thereof. For example, in the depicted embodiment, insulator layers 154 may be silicon nitride layers. In some embodiments, insulator layers 154 include a metal-comprising dielectric material, such as a metal oxide material and/or a metal nitride material.

Insulator layers 154 may be formed by depositing an insulator material over device 100 (e.g., by CVD, PVD, other suitable process, or combinations thereof) and etching the insulator material, such that remainders of the insulator material are disposed over undoped semiconductor layers 152. The as-deposited insulator material may be disposed on tops of gate structures 130 (e.g., tops of gate spacers 134 and dummy gate stacks 132), sidewalls of gate structures 130 (e.g., of gate spacers 134), sidewalls of channel layers 120′, sidewalls of inner spacers 149, and sidewalls of protrusions 105P′. In some embodiments, as a result of properties of a deposition process, a thickness of the insulator material over horizontally oriented surfaces (e.g., tops of undoped semiconductor layers 152 and tops of gate structures 130) may be greater than a thickness of the insulator material over vertically oriented surfaces (e.g., sidewalls of gate structures 130, sidewalls of channel layers 120′, and sidewalls of inner spacers 149). Parameters of the etching may thus be tuned to remove vertically oriented portions of the insulator material, such as that on sidewalls of gate structures 130, sidewalls of channel layers 120′, and sidewalls of inner spacers 149. In such embodiments, as a result of etch loading effects, the etching may also remove horizontally oriented portions of the insulator material on top of gate structures 130, but not (or minimally) horizontally oriented portions and/or vertically oriented portions of the insulator material in bottoms of source/drain recesses 140, such as that disposed on undoped semiconductor layers 152 (i.e., the etching process may thin such portions). In some embodiments, the as-deposited insulator material fills source/drain recesses 140 and the etching recesses the insulator material at least to bottom sacrificial oxide layers 146. The etching may be a dry etch, a wet etch, other suitable etch, or combinations thereof.

Doped semiconductor layers 156 may be formed in source/drain recesses 140 over insulator layers 154 and/or undoped semiconductor layers 152. Doped semiconductor layers 156 fill remainders of source/drain recesses 140, and doped semiconductor layers 156 are coupled to edges/ends of channel layers 120′. In the depicted embodiment, doped semiconductor layers 156 include doped semiconductor layers 158 and doped semiconductor layers 160. Doped semiconductor layers 158 may be formed over channel layers 120′ and partially fill source/drain recesses 140, and doped semiconductor layers 160 may be formed over doped semiconductor layers 158 and/or insulator layers 154 and fill remainders of source/drain recesses 140. Doped semiconductor layers 158 are between channel layers 120′ and doped semiconductor layers 160, and insulator layers 154 are between doped semiconductor layers 160 and undoped semiconductor layers 152. In the depicted embodiment, doped semiconductor layers 158 are discontinuous and formed of discrete and separate portions, each of which is disposed on an end of a respective channel layer 120′ (i.e., portions of doped semiconductor layers 158 disposed on adjacent channel layers 120′ are not connected to one another). In such embodiments, doped semiconductor layers 160 may wrap doped semiconductor layers 158 and/or doped semiconductor layers 160 may extend to and be disposed on inner spacers 149. In some embodiments, one or more of the discrete, separate portions of doped semiconductor layers 158 may wrap a respective channel layer 120′, such that the discrete, separate portions are formed over a top and/or a bottom of the respective channel layer 120′. In some embodiments, the discrete, separate portions extend over and/or to inner spacers 149. In some embodiments, one or more of the discrete, separate portions of doped semiconductor layers 158 are connected. In such embodiments, portions of doped semiconductor layers 160 may be separated from inner spacers 149 by doped semiconductor layers 158. In some embodiments, doped semiconductor layers 158 wrap doped semiconductor layers 160, and doped semiconductor layers 158 are further between inner spacers 149 and doped semiconductor layers 160.

Doped semiconductor layers 158 and doped semiconductor layers 160 include silicon, germanium, silicon germanium, other suitable semiconductor materials, or combinations thereof. In some embodiments, doped semiconductor layers 158 and doped semiconductor layers 160 include the same semiconductor material with different constituent concentrations. For example, doped semiconductor layers 158 and doped semiconductor layers 160 may include silicon germanium and p-type dopant (e.g., boron and/or gallium), but different germanium concentrations and/or different p-type dopant concentrations, such as where source/drain structures 150 belong to p-type transistors. In such example, doped semiconductor layers 158 may have a smaller germanium concentration (e.g., Ge %) and/or a smaller p-type dopant concentration (e.g., B %) than doped semiconductor layers 160. In other words, doped semiconductor layers 160 may be heavily doped semiconductor layers, and doped semiconductor layers 158 may be lightly doped semiconductor layers. In another example, doped semiconductor layers 158 and doped semiconductor layers 160 may include silicon and n-type dopant (e.g., phosphorous and/or arsenic), but different n-type dopant concentrations, such as where source/drain structures 150 belong to n-type transistors. In such example, doped semiconductor layers 158 may have a smaller n-type dopant concentration (e.g., P %) than doped semiconductor layers 160. In some embodiments, doped semiconductor layers 158 and doped semiconductor layers 160 are formed of different semiconductor materials. In some embodiments, doped semiconductor layers 156 are formed of materials and/or include dopants that provide compressive stress in channel layers 120′, such as where source/drain structures 150 belong to p-type transistors. In some embodiments, doped semiconductor layers 156 are formed of materials and/or include dopants that provide tensile stress in channel layers 120′, such as where source/drain structures 150 belong to n-type transistors.

Doped semiconductor layers 158 may be deposited on and/or grown from channel layers 120′, and doped semiconductor layers 160 may be deposited on and/or grown from doped semiconductor layers 158. In some embodiments, doped semiconductor layers 158 and doped semiconductor layers 160 are formed by respective SEG processes, which may implement CVD deposition techniques (e.g., VPE, UHV-CVD, LPCVD, PECVD, or the like), molecular beam epitaxy, other suitable SEG process, or combinations thereof. The SEG processes may use gaseous and/or liquid precursors that interact with the composition of channel layers 120′, doped semiconductor layers 158, or combinations thereof. Epitaxial growth/deposition conditions, such as those described herein, are tuned to selectively deposit (grow) semiconductor material (e.g., silicon germanium) on semiconductor surfaces (e.g., channel layers 120′ and/or doped semiconductor layers 158) while limiting (or preventing) growth of semiconductor material from dielectric surfaces and/or non-semiconductor surfaces (e.g., inner spacers 149, dummy gate stacks 132, gate spacers 134, fin spacers 139, isolation structures 125, or combinations thereof). In some embodiments, doped semiconductor layers 158 and/or doped semiconductor layers 160 are doped during deposition (i.e., in-situ doping), such as by adding dopants to a source material of the SEG processes. In some embodiments, doped semiconductor layers 158 and/or doped semiconductor layers 160 are doped after deposition, such as by an ion implantation process. In some embodiments, annealing is performed to activate dopants in doped semiconductor layers 158, doped semiconductor layers 160, other source/drain regions/features, such as source/drain junction implants, or combinations thereof. Fabrication of source/drain structures 150 may be configured to provide source/drain structures 150 with various dimensions. For example, in some embodiments, a width of source/drain structures 150 (e.g., along the y-direction) is different than a thickness of source/drain structures 150 (e.g., along the z-direction). In some embodiments, such dimension difference is provided to doped semiconductor layers 160 (e.g., widths thereof may be greater than thicknesses thereof).

Referring to FIG. 3M and FIG. 4M, fabrication of device 100 may include forming a dielectric layer 170 over source/drain structures 150. Dielectric layer 170 may fill spaces between adjacent gate structures 130, such as spaces between gate spacers 134 thereof, and spaces between adjacent source/drain structures 150. Forming dielectric layer 170 may include depositing a contact etch stop layer (CESL) 172, depositing an interlayer dielectric (ILD) layer 174 over CESL 172, and performing a CMP and/or other planarization process until reaching dummy gate stacks 132 (e.g., hard masks 138 thereof). In some embodiments, the planarization process may partially remove dummy gate stacks 132, such as hard masks 138 thereof, to expose underlying dummy gate bulks 136 (e.g., poly gates). The planarization process may reduce heights of dummy gate stacks 132 and/or gate spacers 134, in some embodiments.

ILD layer 174 includes a dielectric material including, for example, silicon oxide, carbon doped silicon oxide, silicon nitride, silicon oxynitride, tetraethylorthosilicate (TEOS)-formed oxide, BSG, PSG, borophosphosilicate glass, fluorosilicate glass, xerogel, aerogel, amorphous fluorinated carbon, parylene, benzocyclobutene-based (BCB) dielectric material, polyimide, other suitable dielectric material, or combinations thereof. In some embodiments, ILD layer 174 includes a low-k dielectric material having a dielectric constant that is less than a dielectric constant of silicon dioxide (e.g., k<3.9). In some embodiments, ILD layer 174 includes a dielectric material having a dielectric constant that is less than about 2.5 (i.e., an extreme low-k (ELK) dielectric material), such as porous silicon dioxide, silicon carbide, carbon-doped oxide (e.g., a SiCOH-based material having, for example, Si—CH₃ bonds), or combinations thereof, each of which is tuned/configured to exhibit a dielectric constant less than about 2.5. CESL 172 includes a material different than ILD layer 174, such as a dielectric material that is different than the dielectric material of ILD layer 174. For example, where ILD layer 174 includes a silicon-and-oxygen comprising low-k dielectric material, CESL 172 may include silicon and nitrogen, such as silicon nitride or silicon oxynitride. ILD layer 174 and/or CESL 172 may have a multilayer structure and/or include multiple dielectric materials.

Referring to FIGS. 3N-3Q, FIGS. 4N-4Q, and FIGS. 5B-5D, fabrication of device 100 may include a gate replacement process, which replaces dummy gate stacks 132 and sacrificial oxide layers 146 with gate stacks 180. Gate stacks 180 (which are referred to as high-k/metal gates, in some embodiments) are disposed between respective gate spacers 134, between respective inner spacers 149, between respective channel layers 120′, and between respective channel layers 120′ and respective protrusions 105P′. One or more gate stacks 180 may include a respective gate dielectric 182 and a respective gate electrode 184. In the depicted embodiment, gate stacks 180 may surround and engage respective channel layers 120′, for example, in the Y-Z plane (see, e.g., FIG. 5D). In some embodiments, gate stacks 180 may wrap and/or partially surround respective channel layers 120′ (i.e., be disposed on at least two sides thereof).

Referring to FIG. 3N and FIG. 4N, dummy gate stacks 132 are removed from gate structures 130 to form gate openings 175. Gate openings 175 expose channel regions, which include channel layers 120′ and sacrificial oxide layers 146. In some embodiments, an etching process selectively removes dummy gate stacks 232 (e.g., poly gates) with negligible (to no) removal of dielectric layer 170 (e.g., ILD layer 174 and CESL 172), gate spacers 134, inner spacers 149, sacrificial oxide layers 146, channel layers 120′, or combinations thereof. The etching process is a dry etch, a wet etch, other suitable etch, or combinations thereof. In some embodiments, the etching process uses a patterned mask layer as an etch mask, where the patterned mask layer covers dielectric layer 170 and/or gate spacers 134. In some embodiments, dummy gate dielectrics 135 (e.g., dummy oxide layers) of dummy gate stacks 132 remain.

Referring to FIG. 3O, FIG. 4O, and FIG. 5B, sacrificial oxide layers 146 are removed from channel regions, thereby forming gaps (openings) 178 that expose channel layers 120′. Gate openings 175 are thus extended between channel layers 120′ and between channel layers 120′ and protrusions 105P′. In some embodiments, an etching process selectively removes sacrificial oxide layers 146 with respect to protrusions 105P′, channel layers 120′, gate spacers 134, inner spacers 149, dielectric layer 170, or combinations thereof. In other words, the etching process removes sacrificial oxide layers 146 with negligible (to no) removal of protrusions 105P′, channel layers 120′, gate spacers 134, inner spacers 149, dielectric layer 170, or combinations thereof. For example, an etchant is selected that etches an oxide material (e.g., sacrificial oxide layers 146) at a higher rate than silicon (e.g., channel layers 120′ and protrusions 105P′) and dielectric materials having compositions different than the oxide material (e.g., gate spacers 134, inner spacers 149, CESL 172, ILD layer 174, etc.) (i.e., the etchant has a high etch selectivity with respect to the oxide material). The etching process is a dry etch, a wet etch, other suitable etch, or combinations thereof. In some embodiments, the etching process removes any remainder of dummy gate stacks 232, such as dummy gate dielectrics 135.

Referring to FIG. 3P, FIG. 4P, and FIG. 5C, the present disclosure recognizes that, sometimes, oxide residue on channel layers 120′ may undesirably increase interface trap density (Dᵢₜ) and/or roughness of channel surfaces, which may degrade performance of device 100 (e.g., by increasing drain-induced barrier lowering (DIBL)). The oxide residue may be formed while and/or remain after removing sacrificial semiconductor layers 115, forming sacrificial oxide layers 146, removing sacrificial oxide layers 146, performing other processes associated with fabricating device 100, or combinations thereof. In some embodiments, semiconductor remnants of sacrificial semiconductor layers 115 (e.g., silicon germanium remnants) may remain on channel layers 120′ after removing sacrificial semiconductor layers 115 to form gaps 144 (FIG. 3G). The semiconductor remnants may be oxidized during subsequent processing (e.g., that associated with forming sacrificial oxide layers 146, forming inner spacers 149, removing sacrificial oxide layers 146, or combinations thereof), and the oxidized semiconductor remnants (e.g., germanium oxide remnants and/or silicon germanium oxide remnants) may not be removed by subsequent processing (e.g., that associated with removing sacrificial oxide layers 146). In some embodiments, instead of selectively etching sacrificial semiconductor layers 115 relative to semiconductor layers 120 as described above, sacrificial semiconductor layers 115 may be removed by performing an oxidation process to convert sacrificial semiconductor layers 115 into semiconductor oxide layers (e.g., germanium oxide layers and/or silicon germanium oxide layers) and performing an etching process to remove the semiconductor oxide layers to form gaps 144. In such embodiments, semiconductor oxide remnants (e.g., germanium oxide remnants and/or silicon germanium oxide remnants) may remain on channel layers 120′ after the etching process, and subsequent processing may not or insufficiently remove the semiconductor oxide remnants. In some embodiments, remnants of sacrificial oxide layers 146 (e.g., silicon oxide remnants) and/or other oxide remnants may remain on channel layers 120′.

The present disclosure thus proposes performing a hydrogen treatment HT to remove any residual oxide from channel layers 120′ before forming gate stacks 180. Hydrogen treatment HT may be an annealing process performed in a hydrogen-containing ambient (i.e., a hydrogen anneal). In some embodiments, the hydrogen-containing ambient includes hydrogen radicals (H*), and hydrogen treatment HT may be referred to as a hydrogen radical annealing. The hydrogen radicals may react with and/or break down residual oxide on channel layers 120′, such as germanium oxide (e.g., GeOₓ, such as GeO and/or GeO₂). In some embodiments, gaseous (g) hydrogen radicals (e.g., 2H*, 4H*, 8H*, or combinations thereof) in the hydrogen-containing ambient provided by hydrogen thermal treatment HT may react with residual germanium oxide (e.g., GeO₂ in solid form (s)) on channel layers 120′ to provide gaseous germanium oxide (e.g., GeO), water vapor (e.g., H₂O), germane (e.g., GeH₄), germanium (e.g. Ge), or combinations thereof, such as illustrated by the following reduction reactions:

GeO₂₍ₛ₎+2H*_{(g)}→GeO_{(g)}+H₂O_{(g)}

GeO₂₍ₛ₎+4H*_{(g)}→Ge₍ₛ₎+2H₂O_{(g)}

GeO₂₍ₛ₎+8H*_{(g)}→GeH_{4(g)}+2H₂O_{(g)}

In some embodiments, the hydrogen-containing ambient includes H₂, and hydrogen treatment HT may be referred to as an H₂ anneal. The hydrogen (e.g., H₂) may also react with and/or break down residual oxide on channel layers 120′, such as germanium oxide. In some embodiments, gaseous (g) hydrogen (e.g., H₂) in the hydrogen-containing ambient provided by hydrogen thermal treatment HT may react with residual germanium oxide (e.g., GeO₂) on channel layers 120′ to provide gaseous germanium oxide (e.g., GeO), water vapor (e.g., H₂O), germanium (e.g. Ge), or combinations thereof, such as illustrated by the following reduction reactions:

GeO₂₍ₛ₎+H_{2(g)}→GeO_{(g)}+H₂O_{(g)}

GeO_{(g)}+H_{2(g)}→Ge₍ₛ₎+H₂O_{(g)}

GeO₂₍ₛ₎+2H_{2(g)}→Ge₍ₛ₎+2H₂O_{(g)}

Additional reactions that may be associated with the hydrogen radical annealing and/or the H₂ anneal depending on various parameters thereof include the following:

Ge₍ₛ₎+O_{2(g)}→GeO_{(g)}

GeO₍ₛ₎→GeO_{(g)}

GeH_{4(g)}→Ge_{(g)}+H_{2(g)}

GeO_{(g)}+GeO_{(g)}→GeO₂₍ₛ₎+Ge₍ₛ₎

In some embodiments, the annealing process is a soak anneal, such as an H* soak anneal and/or an H₂ soak anneal. In some embodiments, the annealing process is a spike annealing, such as an H* spike anneal and/or an H₂ spike anneal. In some embodiments, the annealing process is a furnace annealing, such as an H* furnace anneal and/or an H₂ furnace anneal.

Hydrogen treatment HT is configured to sufficiently remove residual oxide from exposed surfaces of channel layers 120′ (e.g., silicon layers), smooth the exposed surfaces of channel layers 120′, provide channel layers 120′ with target profiles and/or target dimensions, or combinations thereof. For example, parameters of hydrogen treatment HT (e.g., a hydrogen anneal) may be controlled and/or tuned to remove germanium oxide and/or cause silicon reflow that may provide channel layers 120′ with smoother surfaces. Hydrogen treatment parameters may include anneal temperature, anneal time, anneal pressure, a flow rate of hydrogen, a flow rate of a carrier gas (e.g., an inert gas, such as nitrogen (e.g., N₂), helium, argon, other inert gas, or combinations thereof), other hydrogen treatment parameters, or combinations thereof. In some embodiments, hydrogen treatment HT is performed with one or more of the following process parameters: an anneal temperature of about 400 degrees Celsius (°C) to about 850 °C, a pressure of about 1 torr to about 100 torr, an anneal time of about 1 second(s) to about 100 s, a ratio of a hydrogen gas (e.g., H₂) to an inert gas (e.g., N₂) that is at least 1% (e.g., 1% to 100%, or combinations thereof. In some embodiments, a hydrogen anneal (e.g., an H* anneal and/or an H₂ anneal) is performed with one or more of the following process parameters: a process temperature of about 600 °C to about 850 °C (e.g., 700 °C), a process pressure of about 10 torr to about 20 torr, a process time of about 10 s to about 100 s (e.g., 30 s), a ratio of hydrogen gas (e.g., H₂) to nitrogen gas (e.g., N₂) that is about 20% to about 60% (e.g., H₂/N₂≈30%), or combinations thereof. The disclosed process parameters are not randomly chosen but are specifically configured to achieve residual oxide removal, channel material reflow, channel profile modification, or combinations thereof. For example, if an anneal temperature is too low (e.g., less than about 400 °C), then hydrogen in the hydrogen-containing ambient (e.g., hydrogen radicals and/or H₂) may not react with residual oxide on the surfaces of channel layers 120′, such that the residual oxide is not removed therefrom, and/or channel material may not be sufficiently heated to cause reflow thereof that may reduce channel surface roughness. On the other hand, if the anneal temperature is too high (e.g., greater than about 850 °C), then hydrogen treatment may cause undesired migration of dopants and/or other constituents into channel layers 120′ and/or source/drain structures 150 that may negatively impact junction overlap and/or worsen short channel effects. In another example, anneal times less than about 10 s may not enable enough removal of residual oxide and/or reflow of channel material, while anneal times greater than about 100 s may expose device 100 to high temperatures for too long, which may cause too much reflow of channel material, undesired channel profile modification, degradation of various features of device 100 (e.g., channel layers 120′ and/or source/drain structures 150), or combinations thereof. As yet another example, a ratio of hydrogen gas (e.g., H₂) to nitrogen gas (e.g., N₂) (or other inert gas) that is less than about 20% may not provide enough hydrogen in the hydrogen-containing ambient to facilitate reduction of the residual oxide by hydrogen (e.g., by hydrogen radicals and/or H₂ in the hydrogen-containing ambient). The specifically configured process parameter ranges are thus provided to improve channel surfaces (e.g., by removing residual oxide from and/or smoothing), such as that which can improve reliability and/or improve overall performance of device 100, without negatively impacting fabrication throughput and/or fabrication complexity. In some embodiments, hydrogen treatment HT heats device 100, features thereof (e.g., channel layers 120′), an ambient/environment containing device 100, or combinations thereof to a temperature (e.g., the annealing temperature) that enables residual oxide removal from channel surfaces and/or smoothing of the channel surfaces.

Hydrogen treatment HT may modify surfaces, profiles, dimensions, and the like of channel layers 120′. For example, hydrogen treatment HT smooths surfaces of channel layers 120′ (e.g., semiconductor layers, such as silicon layers), which may reduce line width roughness (LWR) and/or line edge roughness (LER) thereof, and/or provide channel layers 120′ with different profiles. In some embodiments, high temperatures implemented by hydrogen treatment HT (e.g., about 600 °C to about 850 °C) may facilitate and/or cause silicon (e.g., at surfaces of channel layers 120′) to reflow in a manner that smooths edges and/or corners thereof (e.g., into a configuration that minimizes surface energy), such that cross-sectional profiles of channel layers 120′ along the gate lengthwise direction may change from generally rectangular-shaped (or square-shaped), such as depicted in FIG. 5B, to generally oval-shaped (or circle-shaped), such as depicted in FIG. 5C. In some embodiments, the cross-sectional profiles of channel layers 120′ may remain generally rectangular-shaped, and hydrogen treatment HT may smooth corners of channel layers 120′, such that sharp, squared corners of channel layers 120′ become smooth, rounded corners. Further, since channel layers 120′ have smoother surfaces after hydrogen treatment HT, channel layers 120′ exhibit less LWR/LER after hydrogen treatment HT. In some embodiments, LWR of channel layers 120′ before hydrogen treatment HT (FIG. 5B) is about 1 nm to about 1.2 nm and LWR after hydrogen treatment HT (FIG. 5C) is about 0.9 nm to about 1 nm. Hydrogen treatment HT may thus reduce LWR by about 0.1 nm to about 0.3 nm. The smoother channel surfaces provided by hydrogen treatment HT, along with the reduction and/or elimination of residual oxide (e.g., GeOₓ) from the channel surfaces, may reduce interface trap density at channel/gate dielectric interfaces and/or improve transistor performance (e.g., by reducing subthreshold swing, reducing drain-induced barrier lowering (DIBL) effects, reducing short-channel effects, improving RO performance (e.g., RO gain), and the like).

Channel layers 120′ may have a length along the x-direction (e.g., a sheet length SL), a width along the y-direction (e.g., a sheet width SW), and a height along the z-direction (e.g., a sheet height SH), and hydrogen treatment HT may modify sheet length SL, sheet width SW, sheet height SH, or combinations thereof. For example, sheet height SH may be substantially uniform (i.e., the same) along sheet length SL before hydrogen treatment HT, such as depicted in FIG. 6A, and hydrogen treatment HT may recess portions of channel layers 120′ (e.g., centers thereof), such that sheet height SH varies along sheet length SL after hydrogen treatment HT, such as depicted in FIG. 6B. In such example, sheet height SH may also be substantially uniform (i.e., the same) along sheet width SW before hydrogen treatment HT, such as depicted in FIG. 5B, and hydrogen treatment HT may recess portions of channel layers 120′ (e.g., edges thereof), such that sheet height SH varies along sheet width SW after hydrogen treatment HT, such as depicted in FIG. 5C. In some embodiments, sheet width SW is about 9 nm to about 70 nm (e.g., about 25 nm). In some embodiments, sheet length SL is about 15 nm to about 30 nm. In some embodiments, sheet height SH is about 4 nm to about 8 nm.

In some embodiments, channel layers 120′ have similar cross-sectional profiles along the gate lengthwise direction and the gate widthwise direction (and/or active region lengthwise direction) before hydrogen treatment HT, but different cross-sectional profiles along the gate lengthwise direction and the gate widthwise direction after hydrogen treatment HT. For example, channel layers 120′ may have substantially flat top surfaces and substantially flat bottom surfaces in cross-sectional views along the gate lengthwise direction and the gate widthwise direction before hydrogen treatment HT, such as depicted in FIG. 6A and FIG. 5B, respectively. In contrast, channel layers 120′ may have inwardly bowed surfaces in a cross-sectional view along the gate widthwise direction (FIG. 6B), but outwardly bowed surfaces in a cross-sectional view along the gate lengthwise direction (FIG. 5C), after hydrogen treatment HT. For example, hydrogen treatment HT may recess center/middle portions of channel layers 120′ along the gate widthwise direction, such that channel layers 120′ have concave top surfaces and concave bottom surfaces as depicted in FIG. 6B, and edge/end portions of channel layers 120′ along the gate lengthwise direction, such that channel layers 120′ have convex top surfaces and convex bottom surfaces as depicted in FIG. 5C. In such embodiments, sheet height SH decreases from edges of channel layers 120′ to centers/middles of channel layers 120′ along the gate widthwise direction (FIG. 6B) but increases from edges of channel layers 120′ to centers/middles of channel layers 120′ along the gate lengthwise direction (FIG. 5C).

Referring to FIG. 7A and FIG. 7B, hydrogen treatment HT may thus provide channel layers 120′ with an edge height SHEY and a center height SHCY in a cross-sectional view along the gate lengthwise direction and an edge height SHEX and a center height SHCX in a cross-sectional view along the gate widthwise direction. Further, hydrogen treatment HT may provide edges/ends of channel layers 120′ tilted relative to centers/middles of channel layers 120′ by a tilt angle σ along the gate lengthwise direction and a tilt angle φ along the gate widthwise direction. Edge height SHEY is less than center height SHCY, and a ratio of center height SHCY to edge height SHEY is greater than one. In contrast, edge height SHEX is greater than center height SHCX, and a ratio of center height SHCX to edge height SHEX is less than one. In some embodiments, the ratio of center height SHCY to edge height SHEY is less than or equal to 1.5 (e.g., 1<SHCY/SHEY≤1.5). In some embodiments, the ratio of center height SHCX to edge height SHEX is about 0.6 to about 0.8 (e.g., 0.6≤SHCX/SHEX≤0.8). In some embodiments, center height SHCY is about 0.4 nm to about 1 nm greater than edge height SHEY. In some embodiments, edge height SHEX is about 1.7 nm to about 2.7 nm greater than center height SHCX. In some embodiments, tilt angle σ is less than about −15° (σ≤−15°). In some embodiments, a tilt angle φ is less than about 20° (φ≤20°). With such configurations, channel layers 120′ have a rounded profile in a cross-sectional view along the gate lengthwise direction (which may be referred to as a gate cut profile) and a dog-bone profile in a cross-sectional view along the gate widthwise direction (which may be referred to as a channel cut profile). In some embodiments, parameters of hydrogen treatment HT may be tuned to achieve target profiles of channel layers 120′. For example, increasing anneal temperature and/or anneal time may increase bowing of channel layers 120′ (e.g., by increasing reduction of sheet height SH at centers and/or edges thereof) and thus increase tilt angle σ and/or tilt angle φ.

In some embodiments, center height SHCY is greater than about 5 nm (e.g., about 5 nm to about 6 nm), and edge height SHEY is less than about 5 nm (e.g., about 4 nm to about 5 nm). In some embodiments, edge height SHEY is about 5 nm before hydrogen treatment HT, and hydrogen treatment HT reduces edge height SHEY about 0.2 nm to about 0.5 nm, such that edge height SHEY is about 4.5 nm to about 4.8 nm after hydrogen treatment HT. In some embodiments, center height SHCY is about 5.2 nm to about 5.5 nm when edge height SHEY is about 4.5 nm to about 4.8 nm. In some embodiments, center height SHCX is less than about 5 nm (e.g., about 4.5 nm to about 4.8 nm), and edge height SHEX is greater than about 5 nm (e.g., about 6.2 nm to about 7.3 nm). In some embodiments, center height SHCX is about 5 nm before hydrogen treatment HT, and hydrogen treatment HT reduces center height SHCX about 0.2 nm to about 0.5 nm, such that center height SHCX is about 4.5 nm to about 4.8 nm after hydrogen treatment HT. In some embodiments, edge height SHEX is about 7.0 nm to about 7.3 nm when center height SHCX is about 4.5 nm to about 4.8 nm.

Referring to FIG. 3Q, FIG. 4Q, and FIG. 5D, gate stacks 180 are formed in gate openings 175 and/or gaps 178. For example, gate dielectrics 182 are formed in and partially fill gate openings 175 and gaps 178. Gate dielectrics 182 are disposed on respective channel layers 120′, respective inner spacers 149, respective gate spacers 134, isolation structures 125, or combinations thereof. Gate dielectrics 182 include at least one dielectric layer, such as an interfacial layer and/or a high-k dielectric layer. Interfacial layers include a dielectric material, such as SiO₂, SiGeOₓ, HfSiO, SiON, other dielectric material, or combinations thereof. Interfacial layers are formed by thermal oxidation, chemical oxidation, ALD, CVD, other process, or combinations thereof. High-k dielectric layers include a high-k dielectric material, which generally refers to a dielectric material having a dielectric constant greater than a dielectric constant of silicon dioxide, such as HfO₂, HfSiO, HfSiO₄, HfSiON, HfLaO, HfTaO, HfTiO, HfZrO, HfAlOx, ZrO, ZrO₂, ZrSiO₂, AlO, AlSiO, Al₂O₃, TiO, TiO₂, LaO, LaSiO, LaO₃, La₂O₃, Ta₂O₃, Ta₂O₅, Y₂O₃, SrTiO₃, BaZrO, BaTiO₃, (Ba, Sr)TiO₃ (BST), HfO₂—Al₂O₃, other high-k dielectric material, or combinations thereof. High-k dielectric layers are formed by ALD, CVD, PVD, an oxide-based deposition process, other process, or combinations thereof. In some embodiments, high-k dielectric layers include a hafnium-based oxide (e.g., HfO₂) layer. In some embodiments, high-k dielectric layers include a zirconium-based oxide (e.g., ZrO₂) layer.

Gate electrodes 184 are formed in and fill remainders of gate openings 175 and gaps 178. Gate electrodes 184 are disposed on gate dielectrics 182. Gate electrodes 184 include an electrically conductive layer formed of an electrically conductive material, such as Al, Cu, Ti, Ta, W, Mo, Co, TaN, NiSi, CoSi, TiN, WN, TiAl, TiAlN, TaCN, TaC, TaSiN, other electrically conductive material, or combinations thereof. In some embodiments, the electrically conductive layer includes a work function layer tuned to have a desired work function (e.g., an n-type work function or a p-type work function). The work function layer includes work function metal(s) and/or alloys thereof, such as Ti, Ta, Al, Ag, Mn, Zr, W, Ru, Mo, TiC, TiAl, TiAlC, TiAlSiC, TaC, TaCN, TaSiN, TiSiN, TiN, TaN, TaSN, WN, WCN, ZrSi₂, MoSi₂, TaSi₂, NiSi₂, TaAl, TaAlC, TaSiAlC, TiAlN, or combinations thereof. In some embodiments, the electrically conductive layer includes a bulk layer over the gate dielectric and/or the work function layer. The bulk layer may include Al, W, Cu, Ti, Ta, TiN, TaN, polysilicon, other suitable metal(s) and/or alloys thereof, or combinations thereof. In some embodiments, the electrically conductive layer includes a barrier layer over the work function layer and/or the gate dielectric. The barrier layer includes a material that may prevent diffusion and/or reaction of constituents between adjacent layers and/or promote adhesion between adjacent layers, such as between the work function layer and the bulk layer. In some embodiments, the barrier layer includes metal and nitrogen, such as titanium nitride, tantalum nitride, tungsten nitride, titanium silicon nitride, tantalum silicon nitride, other suitable metal nitride, or combinations thereof.

Forming gate stacks 180 may include depositing gate dielectric material (e.g., interfacial layers, high-k dielectric layers, etc.) that partially fill gate openings 175 and/or gaps 178, depositing gate electrode material (e.g., work function layers, barrier layers, bulk layers, etc.) over the gate dielectric material that fills remainders of gate openings 175 and/or gaps 178, and performing a planarization process (e.g., CMP) to remove portions of the gate dielectric material and/or portions of the gate electrode material over dielectric layer 170. In some embodiments, fabrication of device 100 may further include etching back gate stacks 180 and forming hard masks (e.g., self-aligned cap (SAC) structures) over the etched-back gate stacks 180. The SAC structures include a material that is different than dielectric layer 170 and/or subsequently formed dielectric layers to achieve etch selectivity. In some embodiments, the SAC structures include silicon and nitrogen and/or carbon, such as silicon nitride, silicon oxynitride, silicon carbide, silicon oxycarbide, silicon carbonitride, silicon oxycarbonitride, other silicon nitride, other silicon carbide, or combinations thereof. In some embodiments, the SAC structures include metal and oxygen and/or nitrogen, such as aluminum oxide, aluminum nitride, aluminum oxynitride, zirconium oxide, zirconium nitride, hafnium oxide, zirconium aluminum oxide, other metal oxide, other metal nitride, or combinations thereof.

Device 100 may thus include at least one transistor T. Transistor T may include respective channels (e.g., channel layers 120′), respective source/drains (e.g., source/drain structures 150), and a respective gate (e.g., gate stack 180). In some embodiments, transistor T is a p-type transistor. For example, transistor T may include silicon channels (e.g., channel layers 120′ may be silicon layers, which may be n-doped) and silicon germanium epitaxial source/drains (e.g., doped semiconductor layers 160 may be p-doped silicon germanium structures). In some embodiments, transistor T is an n-type transistor. For example, transistor T may include silicon channels (e.g., channel layers 120′ may be silicon layers, which may be p-doped) and silicon epitaxial source/drains (e.g., doped semiconductor layers 160 may be n-doped silicon structures). Gate stack 180 is disposed between the respective source/drains (e.g., source/drain structures 150) (FIG. 3Q), and inner spacers 149 are disposed between gate stack 180 and the respective source/drains. Further, gate stack 180 engages respective channels (e.g., channel layers 120′), and the respective channels extend between the respective source/drains (e.g., source/drain structures 150) (FIG. 3Q). In the depicted embodiment, transistor T is a GAA transistor. Accordingly, gate stack 180 may surround its respective channel layers, and along the gate lengthwise direction (FIG. 5D), gate stack 180 may include a gate dielectric (e.g., gate dielectric 182) and a gate electrode (e.g., gate electrode 184) that surrounds its respective channels. In some embodiments, gate stack 180 may wrap and/or partially surround its respective channel layers (i.e., disposed on at least two sides thereof), such as where transistor T is a fork-sheet transistor or other type/configuration of multigate transistor. Since gate stack 180 is formed in gaps 178 and changes in channel surfaces and/or channel profiles arising from hydrogen treatment HT may result in profile changes to gaps 178, hydrogen treatment HT may also impact gate profile. For example, along the gate widthwise direction (FIG. 3Q), gate stacks 180 may have outwardly bowing and/or convex top surfaces and outwardly bowing and/or convex bottom surfaces that interface with the inwardly bowing bottom surfaces and the inwardly bowing top surfaces, respectively, of channel layers 120′, such as depicted in an enlarged portion Q of a channel region of device 100 in FIG. 3Q. Further, along the gate lengthwise direction (FIG. 5D), gate stacks 180 may have inwardly bowing and/or concave top surfaces and inwardly bowing and/or concave bottom surfaces between channel layers 120′, which may interface with the outwardly bowing bottom surfaces and the outwardly bowing top surfaces, respectively, of channel layers 120′. Gate stacks 180 may thus exhibit rounded profiles and/or rounded corners between channel layers 120′ as a result of hydrogen treatment HT.

Because transistor T is fabricated using disposable/dummy oxide interposers (e.g., sacrificial oxide layers 146), source/drain structures 150 exhibit improved stress characteristics and/or transistor T exhibits improved performance. For example, because sacrificial semiconductor layers 115 are replaced with sacrificial oxide layers 146 before source/drain fabrication, constituents from dummy interposers (e.g., sacrificial semiconductor layers 115) will not migrate into channel layers 120′ during fabrication of source/drain structures 150, such as migration of germanium that may occur during thermal processes associated with such fabrication. Reducing and/or preventing migration of constituents (e.g., germanium) from the dummy interposers hinders undesired changes in stress characteristics of channel layers 120′, such as the undesired introduction of tensile stress into compressively stressed channel layers, that may negatively impact performance of p-type transistors. Transistors fabricated according to the disclosed methods (e.g., which implement sacrificial oxide layers 146) may thus exhibit improved performance, such as less channel resistance and/or improved stress characteristics (e.g., minimal to no tensile stress). In some instances, transistors, such as p-type transistors, fabricated as described herein (i.e., using dummy oxide interposers) exhibit less leakage current, less parasitic capacitance, less channel resistance, less bottom source/drain insulation RO penalty, or combinations thereof than p-type transistors having bottom source/drain insulation fabricated using dummy semiconductor (e.g., SiGe) interposers.

Further, because transistor T is fabricated using hydrogen treatment HT, transistor T exhibits improved performance. For example, because hydrogen treatment HT removes residual oxide (e.g., germanium oxide) from surfaces of channel layers 120′ and/or smooths the surfaces of channel layers 120′ before forming gate stack 180, interface trap density (Dᵢₜ) observed at channel/gate interfaces of transistor T is lower than interface trap density observed at channel/gate interfaces of transistors fabricated without hydrogen treatment HT. Further, LWR/LER of channel layers 120′ of transistor T is less than LWR/LER of channel layers of transistors fabricated without hydrogen thermal treatment HT. The reduced interface trap density and/or the reduced LWR/LER has been observed to reduce drain-induced barrier lowering (DIBL) and/or reduce subthreshold swing (SS), among other improvements. Further, in assessing performance of transistors fabricated according to the disclosed methods using ring oscillators (ROs), it has been observed that RO performance may be improved by about 1% by implementing hydrogen treatment HT to remove residual oxide from channel surfaces and/or smooth channel surfaces before forming gates. Different embodiments may have different advantages, and no particular advantage is required of any embodiment.

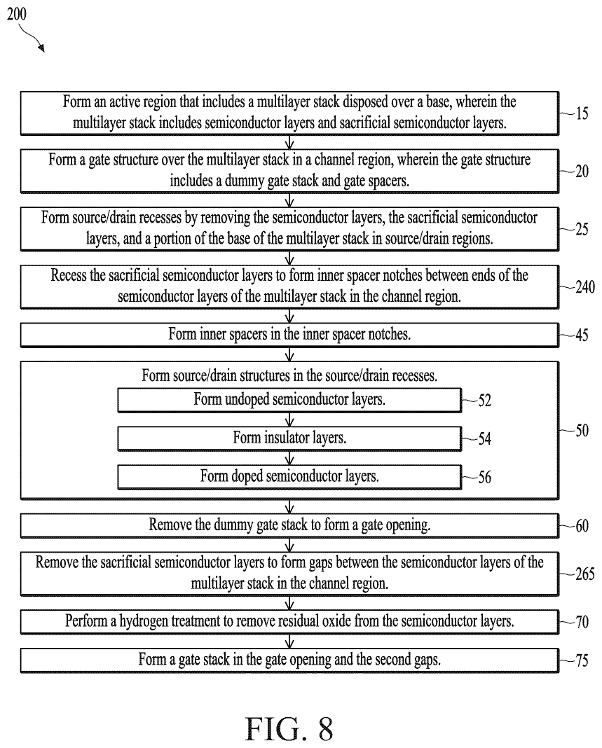

FIG. 8 is a flow chart of a method 200, in portion or entirety, for fabricating multigate devices according to various aspects of the present disclosure. Method 200 is similar in many respects to method 10. Accordingly, similar features in method 200 and method 10 are identified by the same reference numbers for clarity and simplicity. For example, method 200 includes forming an active region that includes a multilayer stack (including sacrificial semiconductor layers and semiconductor layers disposed over a base at block 15, forming a gate structure over the multilayer stack in a channel region at block 20, and forming source/drain recesses by removing the semiconductor layers, the sacrificial semiconductor layers, and a portion of the base in source/drain regions at block 25. In contrast to method 10, method 200 omits processing associated with forming dummy oxide interposers (e.g., sacrificial dielectric layers). Accordingly, after forming source/drain recesses, method 200 may further include recessing the sacrificial semiconductor layers (instead of the sacrificial dielectric layers) to form inner spacer notches between ends of the semiconductor layers of the multilayer stack in the channel region at block 240 and forming inner spacers in the inner spacer notches at block 45. Method 200 further includes forming source/drain structures in the source/drain recesses at block 50 (which may include forming undoped semiconductor layers at block 52, forming insulator layers at block 54, and forming doped semiconductor layers at block 56) and removing the dummy gate stack to form a gate opening at block 60. Method 200 may then include removing the sacrificial semiconductor layers (also referred to as dummy (and/or disposable) semiconductor interposers (DSIs)) to form gaps between the semiconductor layers of the multilayer stack in the channel region at block 265 and forming a gate stack in the gate opening and the second gaps at block 75. Method 200 further includes performing a hydrogen treatment (e.g., a hydrogen anneal) to remove residual oxide from the semiconductor layers at block 70 before forming the gate stack in the gate opening at block 75. In some embodiments, the hydrogen treatment may modify profiles of the semiconductor layers (e.g., by slightly etching the semiconductor layers, thereby modifying dimensions thereof). In some embodiments, a dielectric layer (e.g., an interlayer dielectric layer and/or an etch stop layer) may be formed over the source/drain structures. Additional processing is contemplated by the present disclosure. Additional steps may be provided before, during, and after method 200, and some of the steps described may be moved, replaced, or eliminated for additional embodiments of method 200. The discussion that follows illustrates devices that may be fabricated according to method 200.

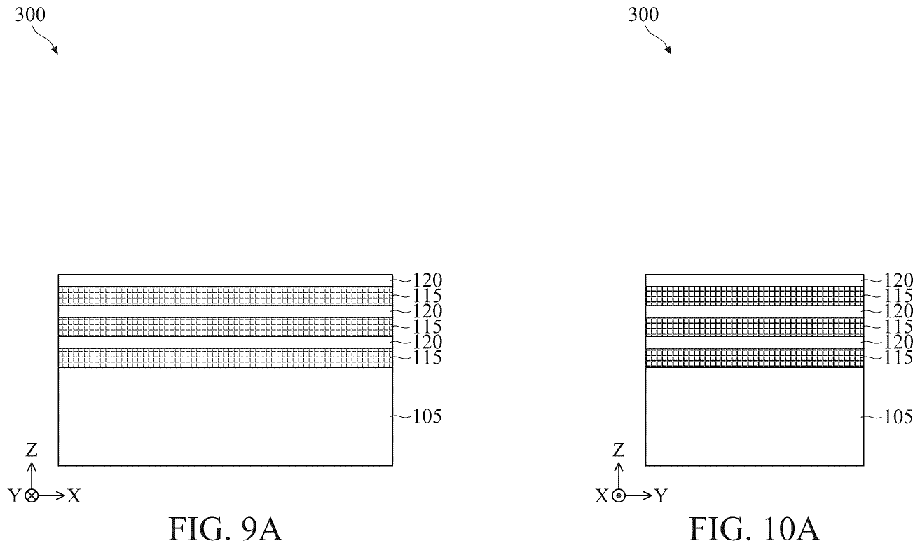

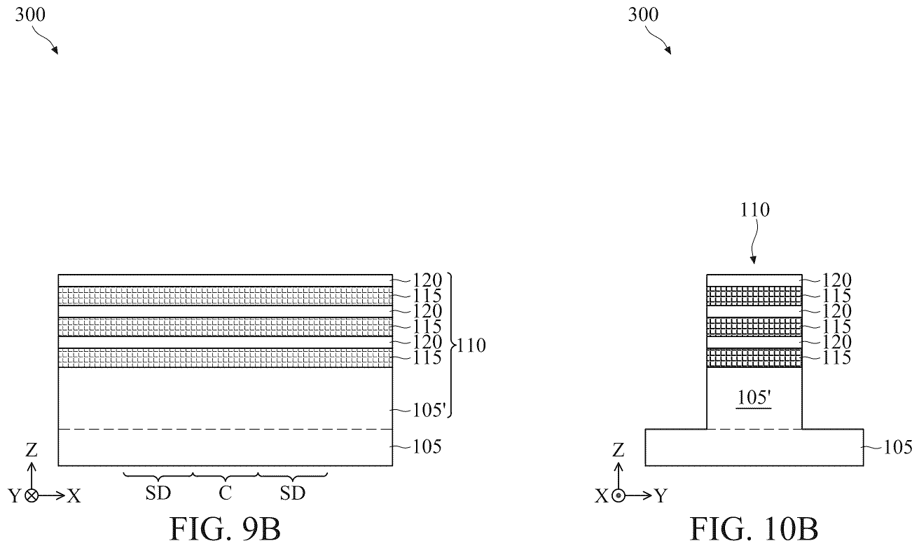

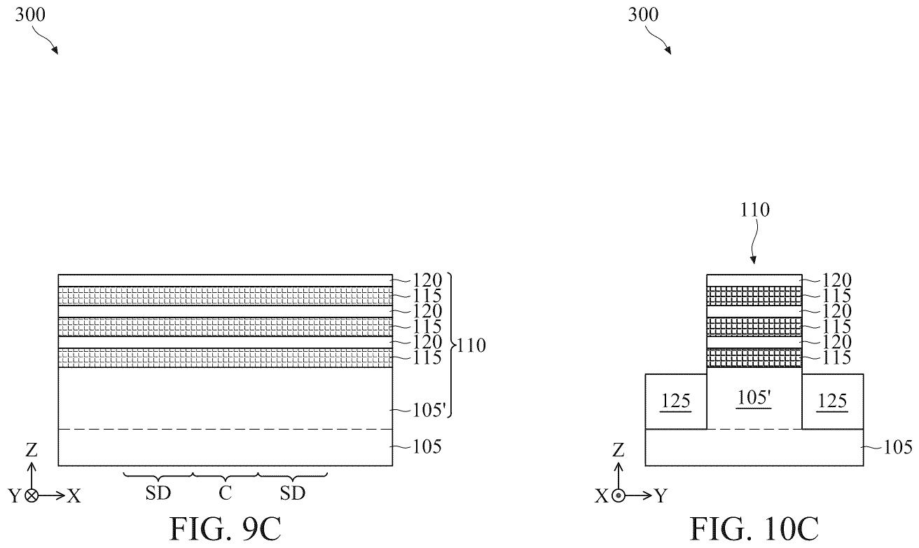

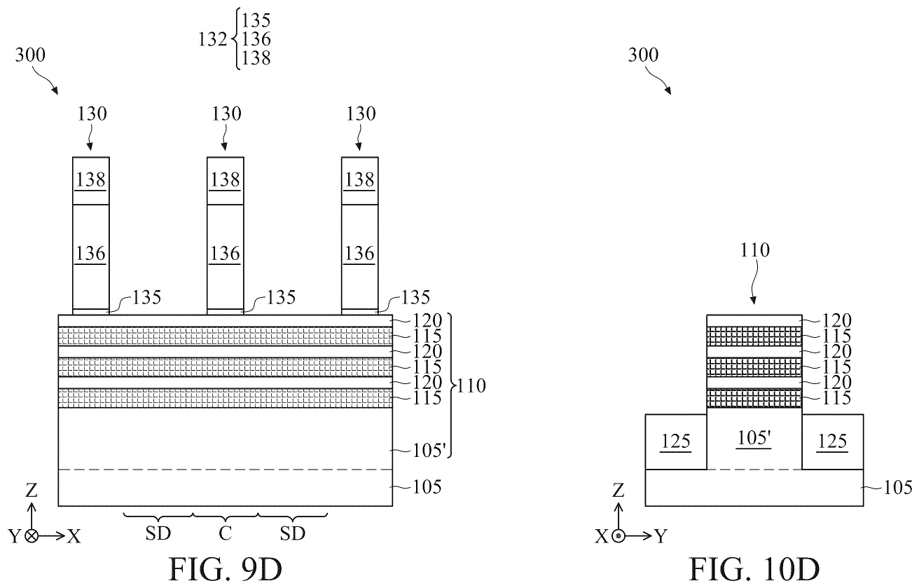

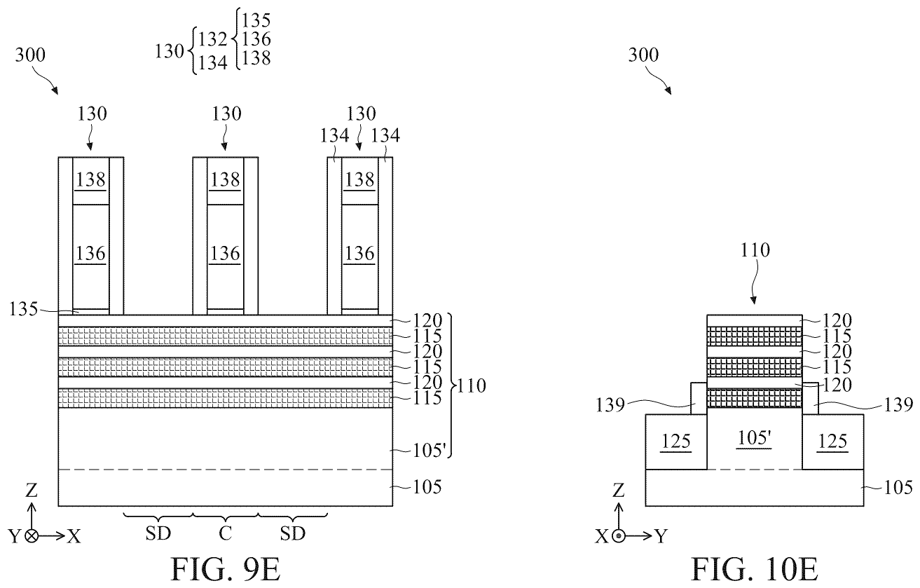

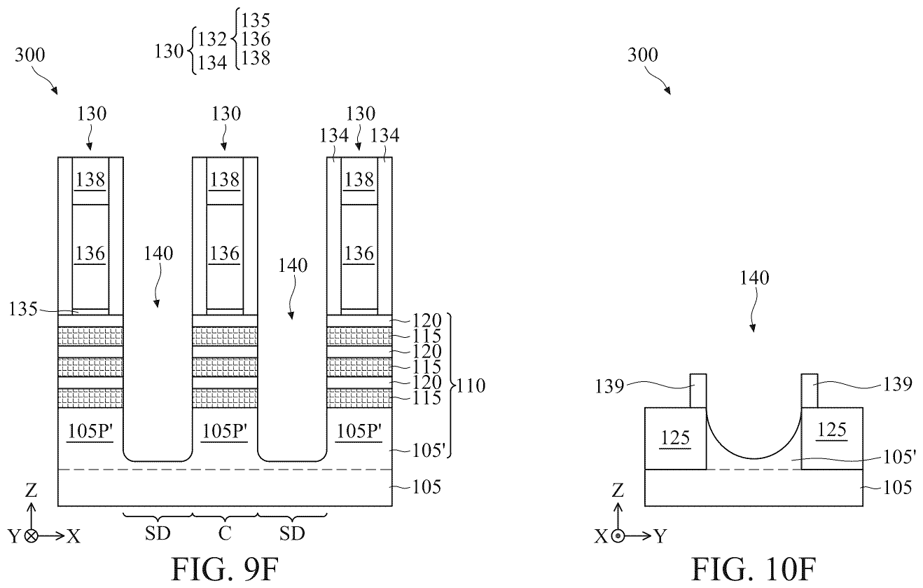

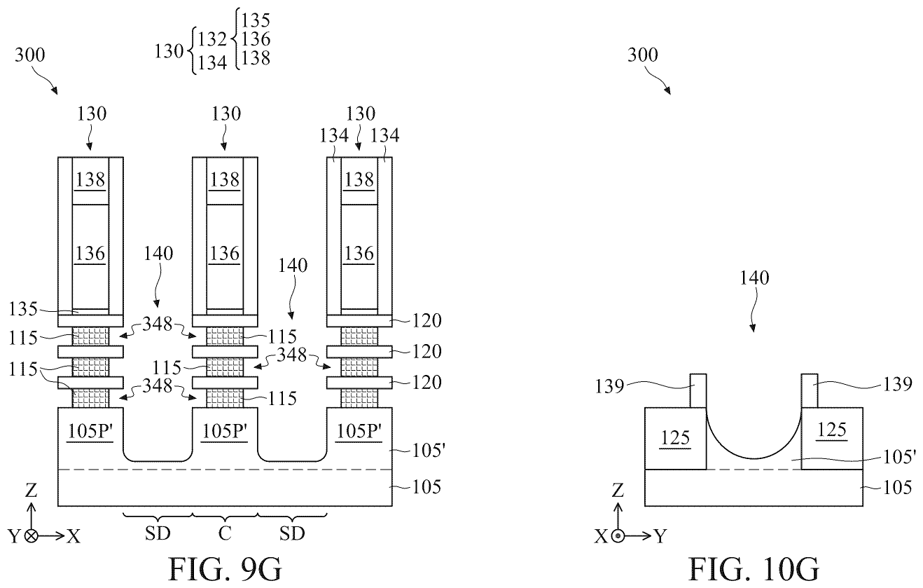

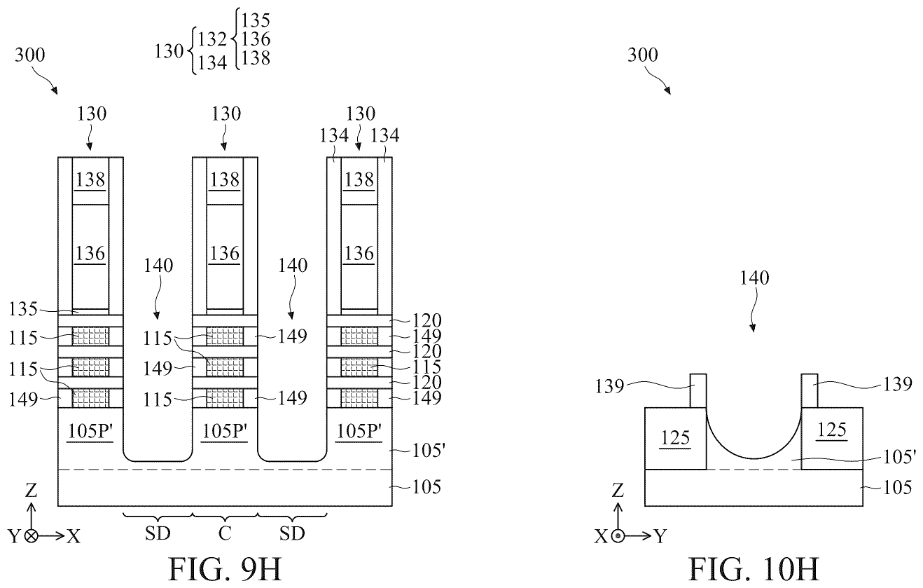

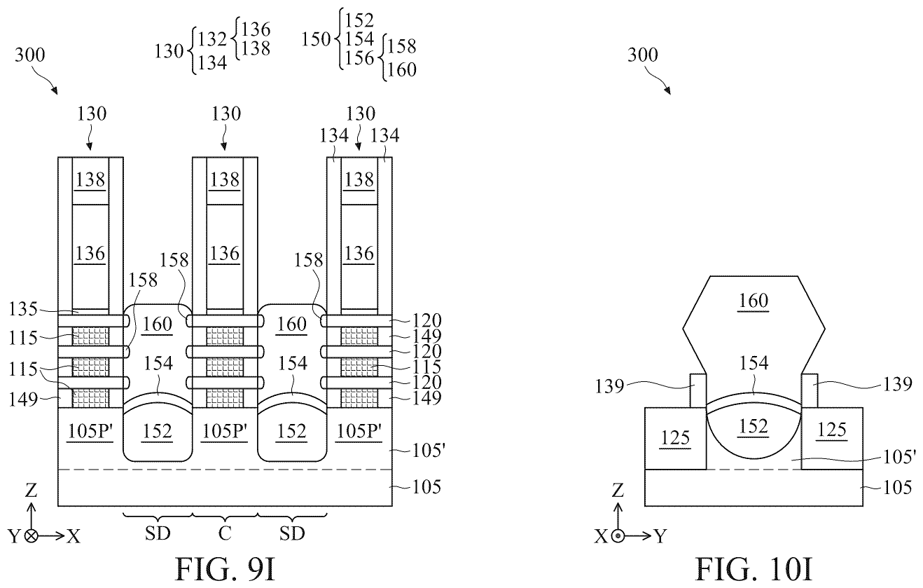

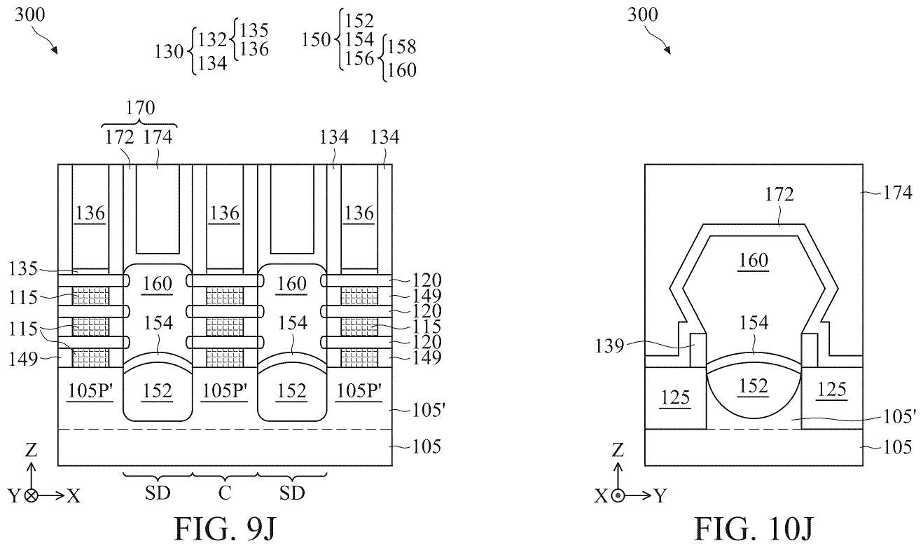

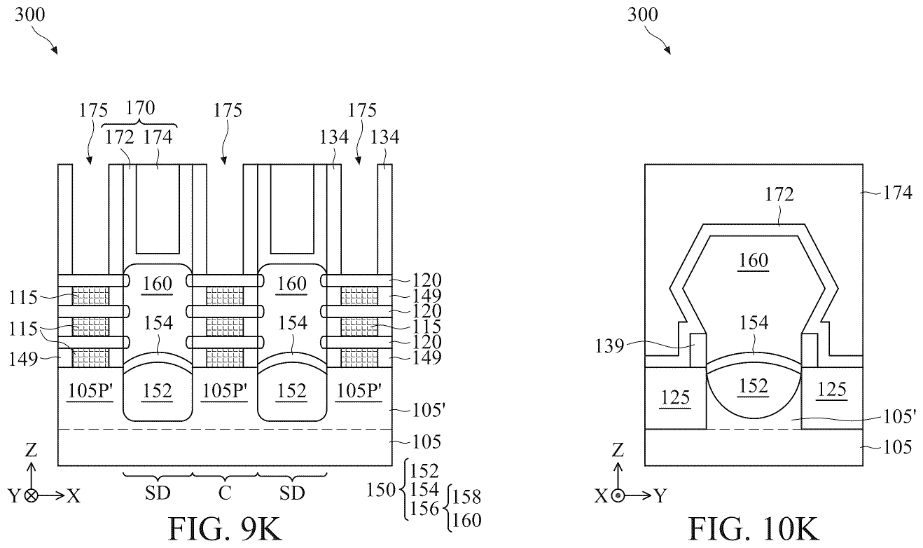

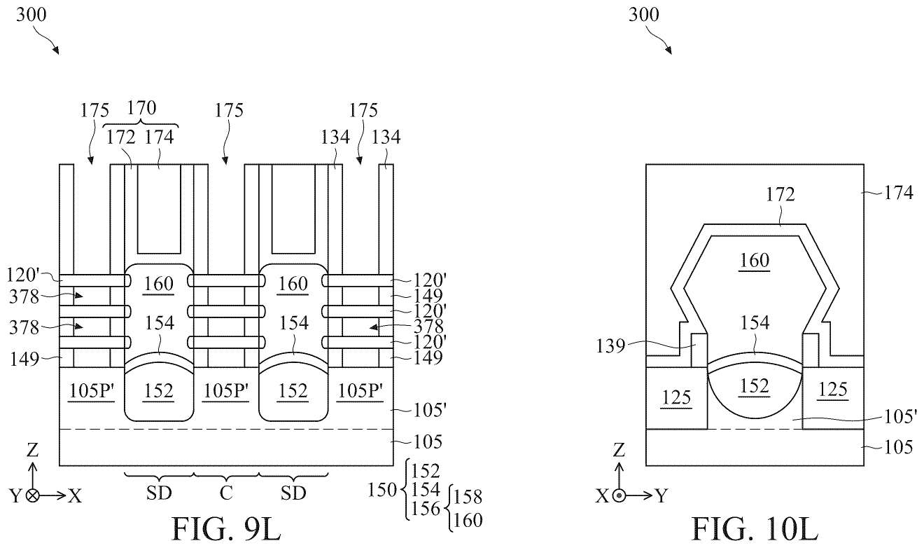

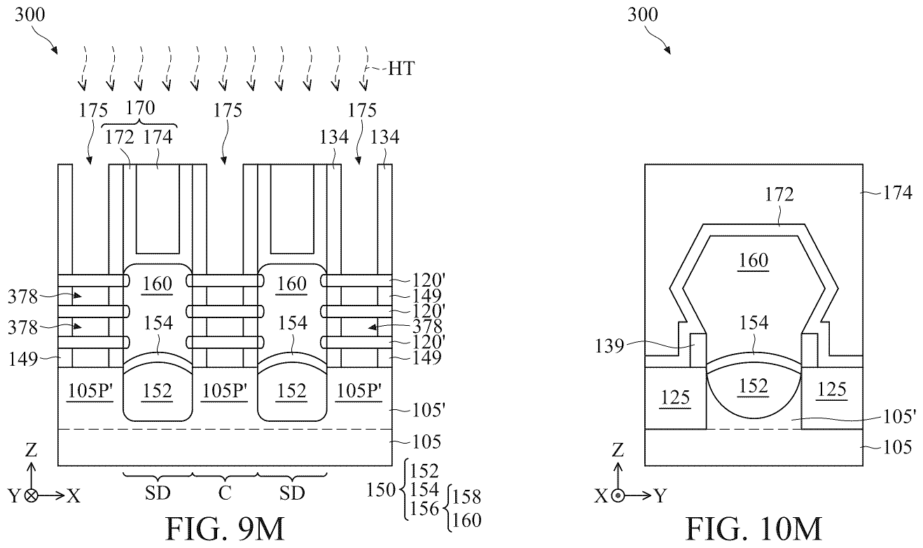

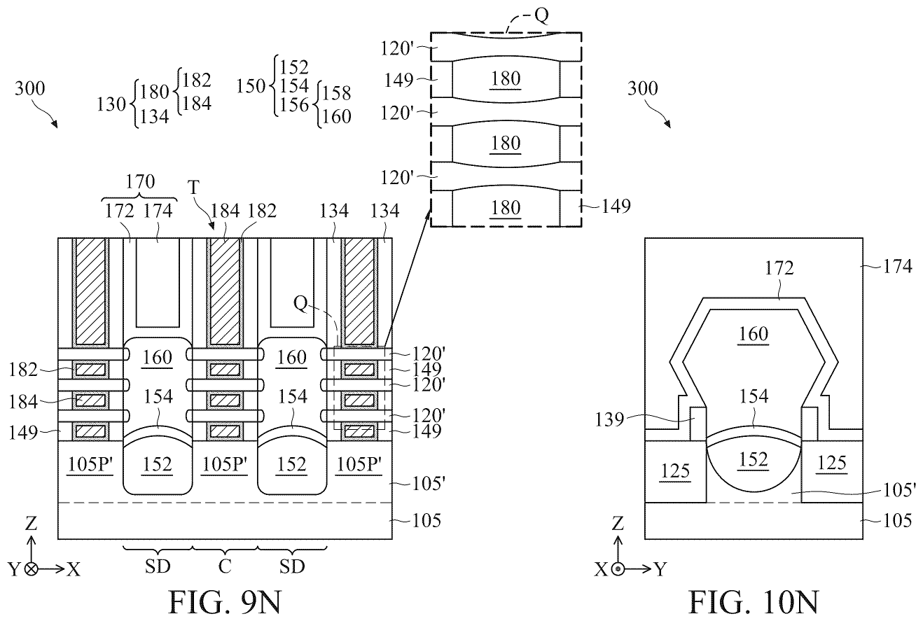

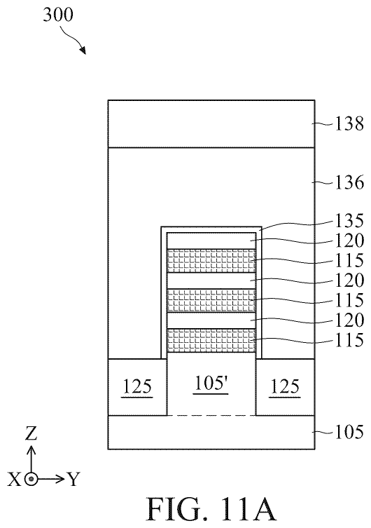

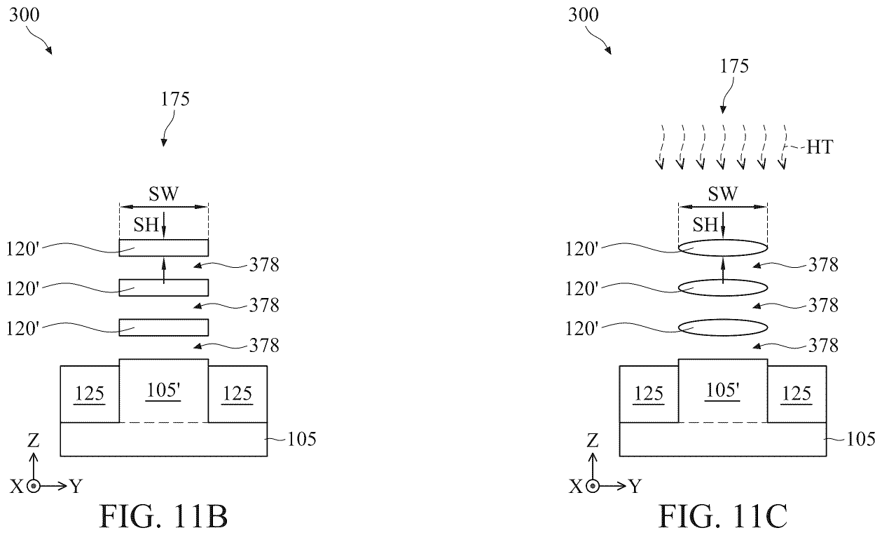

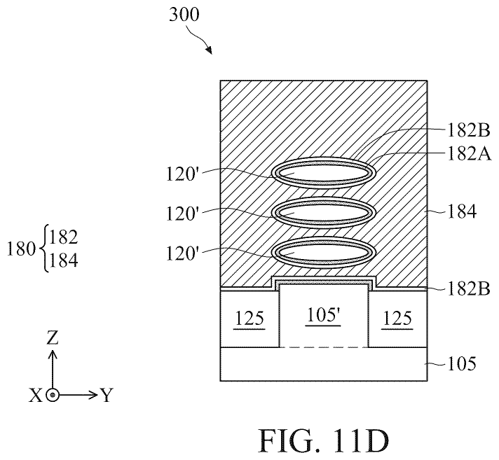

FIGS. 9A-9N are diagrammatic cross-sectional views of a device 300, in portion or entirety, along an active region lengthwise direction (and/or a gate widthwise direction) at various stages of fabrication (such as those associated with method 200 of FIG. 8) according to various aspects of the present disclosure. FIGS. 10A-10N are diagrammatic cross-sectional views of device 300, in portion or entirety, along an active region widthwise direction (and/or a gate lengthwise direction) at various stages of fabrication (such as those associated with method 200 of FIG. 8) according to various aspects of the present disclosure. FIGS. 10A-10N correspond with the stages of fabrication of FIGS. 9A-9N, respectively. FIGS. 11A-11D are cross-sectional views of device 300, in portion or entirety, along an active region widthwise direction (and/or a gate lengthwise direction) at various stages of fabrication (such as those associated with method 200 of FIG. 8) according to various aspects of the present disclosure. FIG. 11A corresponds with the stage of fabrication of FIG. 9D and FIG. 10D, FIG. 11B corresponds with the stage of fabrication of FIG. 9L and FIG. 10L, FIG. 11C corresponds with the stage of fabrication of FIG. 9M and FIG. 10M, and FIG. 11D corresponds with the stage of fabrication of FIG. 9N and FIG. 10N. In some embodiments, FIGS. 9A-9N may be cross-sectional views of device 300 along line A-A of FIG. 2, FIGS. 10A-10N may be cross-sectional views of device 300 along line B-B of FIG. 2, and FIGS. 11A-11D may be cross-sectional views of device 300 along line C-C of FIG. 2. FIGS. 9A-9N, FIGS. 10A-10N, and FIGS. 11A-11D are discussed concurrently herein for ease of description and understanding. Further, the fabrication process of FIGS. 9A-9N, FIGS. 10A-10N, and FIGS. 11A-11D is similar in many respects to the fabrication process of FIGS. 3A-3Q, FIGS. 4A-4Q, and FIGS. 5A-5D. Accordingly, similar features in FIGS. 3A-3Q, FIGS. 4A-4Q, FIGS. 5A-5D, FIGS. 9A-9N, FIGS. 10A-10N, and FIGS. 11A-11D are identified by the same reference numbers for clarity and simplicity. FIGS. 9A-9N, FIGS. 10A-10N, and FIGS. 11A-11D have been simplified for the sake of clarity to better understand the inventive concepts of the present disclosure. Additional features may be added in device 300, and some of the features described below may be replaced, modified, or eliminated in other embodiments of device 300.

After undergoing processing associated with FIG. 8, FIGS. 9A-9N, FIGS. 10A-10N, and FIGS. 11A-11D, device 300 may include at least one GAA transistor. In some embodiments, device 300 is processed to form a p-type transistor. In some embodiments, device 300 is processed to form an n-type transistor. In some embodiments, device 300 is processed to form an n-type transistor and a p-type transistor. In such embodiments, device 300 may include a CMOS transistor. Device 300 may be included in a microprocessor, a memory, other IC device, or combinations thereof. In some embodiments, device 300 is a portion of an IC chip, an SoC, or portion thereof, and device 300 may include various passive electronic devices and/or active electronic devices, such as resistors, capacitors, inductors, diodes, PFETs, NFETs, MOSFETs, CMOS transistors, BJTs, LDMOS transistors, high voltage transistors, high frequency transistors, other suitable components, or combinations thereof.

Referring to FIG. 8, FIG. 9A, FIG. 10A, FIG. 9B, and FIG. 10B, fabrication of device 300 may include forming and/or receiving a device precursor, which may include a substrate 105 and a multilayer stack 110, such as described above with reference to FIG. 2, FIG. 3A, FIG. 4A, FIG. 3B, and FIG. 4B. For example, multilayer stack 110 may include sacrificial semiconductor layers 115 and semiconductor layers 120, multilayer stack 110 may be disposed over base layer 105′, and multilayer stack 110 may correspond with and/or define active region 122. Referring to FIG. 8, FIG. 9C, and FIG. 10C, isolation structures 125 may be formed adjacent to and around a lower portion of multilayer stack 110, such as described above with reference to FIG. 2, FIG. 3C, and FIG. 4C. Referring to FIG. 8, FIG. 9D, FIG. 10D, FIG. 11A, FIG. 9E, and FIG. 10E, gate structures 130 may be formed over channel regions of active region 122 and between respective source/drain regions of active region 122, such as described above with reference to FIG. 2, FIG. 3D, FIG. 4D, FIG. 5A, FIG. 3E, and FIG. 4E. One or more gate structures 130 may include a respective dummy gate stack 132 and respective gate spacers 134.

Referring to FIG. 8, FIG. 9F, and FIG. 10F, a source/drain etch removes portions of multilayer stack 110 that are not covered by gate structures 130, thereby forming source/drain recesses (trenches) 140, such as described above with reference to FIG. 3F and FIG. 4F. In contrast to fabrication of device 100, referring to FIG. 8, FIG. 9G, and FIG. 10G, an etching process (e.g., an anisotropic etch) laterally recesses sacrificial semiconductor layers 115 to form notches 348 under gate structures 130 (e.g., under gate spacers 134 thereof). For example, the etching process may laterally etch (e.g., along the x-direction and/or the y-direction) sacrificial semiconductor layers 115 to reduce their lengths along the x-direction, such that lengths of sacrificial semiconductor layers 115 are less than lengths of semiconductor layers 120. Sacrificial semiconductor layers 115 may be removed from ends of semiconductor layers 120, thereby exposing tops and bottoms of ends of semiconductor layers 120. In some embodiments, notches 348 laterally extend (e.g., along the x-direction) under dummy gate stacks 132.

Referring to FIG. 8, FIG. 9H, and FIG. 10H, inner spacers 149 are formed in notches 248, and remainders of sacrificial semiconductor layers 115 are disposed between respective inner spacers 149. Inner spacers 149 may replace ends of sacrificial semiconductor layers 115, and inner spacers 149 may be disposed under gate spacers 134 along sidewalls of sacrificial semiconductor layers 115. Further, inner spacers 149 are disposed between ends of respective semiconductor layers 120, and bottom inner spacers 149 are disposed between ends of respective bottom semiconductor layers 120 and respective protrusions 105P′. Inner spacers 149 may be formed in notches 248 as described with reference to FIG. 3K and FIG. 4K. In some embodiments, inner spacers 149, including respective manufacturing steps described above (e.g., with reference to FIG. 9G, FIG. 10G, FIG. 9H, and FIG. 10H), are omitted.

Referring to FIG. 8, FIG. 9I, and FIG. 10I, source/drain structures 150 are formed in source/drain recesses 140, such as described with reference to FIG. 3L and FIG. 4L. Referring to FIG. 8, FIG. 9J, and FIG. 10J, fabrication of device 300 may include forming dielectric layer 170 over source/drain structures 150, such as described with reference to FIG. 3M and FIG. 4M. Referring to FIG. 8, FIGS. 9K-9N, FIGS. 10K-10N, and FIGS. 11B-11D, fabrication of device 300 may include a gate replacement process, which replaces dummy gate stacks 132 and sacrificial semiconductor layers 115 (instead of sacrificial dielectric layers 146) with gate stacks 180. For example, referring to FIG. 8, FIG. 9K, and FIG. 10K, dummy gate stacks 132 are removed from gate structures 130 to form gate openings 175, such as described above with reference to FIG. 3N and FIG. 4N. When fabricating device 300 according to method 200, gate openings 175 expose channel regions, which include semiconductor layers 120 and sacrificial semiconductor layers 115, instead of sacrificial oxide layers 146. In some embodiments, an etching process selectively removes dummy gate stacks 232 (e.g., poly gates) with negligible (to no) removal of dielectric layer 170, gate spacers 134, inner spacers 149, sacrificial semiconductor layers 115, semiconductor layers 120, or combinations thereof. The etching process is a dry etch, a wet etch, other suitable etch, or combinations thereof. In some embodiments, the etching process uses a patterned mask layer as an etch mask, where the patterned mask layer covers dielectric layer 170 and/or gate spacers 134. In some embodiments, dummy gate dielectrics 135 (e.g., dummy oxide layers) of dummy gate stacks 132 remain.

Referring to FIG. 8, FIG. 9L, FIG. 10L, and FIG. 11B, an etching process selectively removes sacrificial semiconductor layers 115 exposed by gate openings 175, thereby forming gaps 378 in channel regions. Semiconductor layers 120 remaining in channel regions are suspended over base protrusions 105P′ after removing sacrificial semiconductor layers 115. In the depicted embodiment, each channel region has three suspended semiconductor layers 120, which may be referred to hereafter as channel layers 120′ hereafter, such as described above with reference to FIG. 3G and FIG. 4G. In some embodiments, after removing sacrificial semiconductor layers 115, another etching process may be performed to modify a profile of channel layers 120′ to provide target dimensions and/or target shapes thereof.

The etching process used to form gate openings 375 may selectively remove sacrificial semiconductor layers 115 with respect to substrate 105, semiconductor layers 120, gate spacers 134, inner spacers 149, dielectric layer 170 (e.g., ILD layer 174 thereof), or combinations thereof. In other words, the etching process removes sacrificial semiconductor layers 115 with negligible (to no) removal of substrate 105, semiconductor layers 120, gate spacers 134, inner spacers 149, dielectric layer 170, or combinations thereof. In some embodiments, an etchant is selected for the etching process that etches silicon germanium (e.g., sacrificial semiconductor layers 115) at a higher rate than silicon (e.g., semiconductor layers 120 and base layer 105′) and dielectric materials (e.g., gate spacers 134, inner spacers 149, dielectric layer 170, and the like). The etching process is a dry etch, a wet etch, other suitable etch, or combinations thereof. In some embodiments, before the etching process, an oxidation process may be performed to convert sacrificial semiconductor layers 115 into semiconductor oxide layers (e.g., silicon germanium oxide layers). In such embodiments, the etching process removes semiconductor oxide layers to form gaps 378. In some embodiments, the etching process removes any remainder of dummy gate stacks 232, such as dummy gate dielectrics 135.

Referring to FIG. 8, FIG. 9M, FIG. 10M, and FIG. 11C, hydrogen treatment HT is performed to remove any residual oxide (e.g., germanium oxide) from channel layers 120′ before forming gate stacks 180, such as described above with reference to FIG. 3P, FIG. 4P, and FIG. 5C. Hydrogen treatment HT may be an annealing process performed in a hydrogen-containing ambient (i.e., a hydrogen anneal), and hydrogen from the hydrogen-containing ambient (e.g., hydrogen radicals and/or H₂) may react with and/or break down residual oxide on channel layers 120′, such as germanium oxide (e.g., GeOₓ, such as GeO and/or GeO₂). Hydrogen treatment HT may modify surfaces, profiles, dimensions, and the like of channel layers 120′ of device 300, such that channel layers 120′ of device 300 may have surfaces, profiles, and dimensions similar to that described above with reference to FIG. 3P, FIG. 4P, FIG. 5C, FIG. 6A, FIG. 6B, FIG. 7A, and FIG. 7B. For example, hydrogen treatment HT may provide channel layers 120′ with reduced LWR, smoother channel surfaces, negligible to no residual oxide thereon, reduced interface trap density, different profiles in different cross-sectional views (e.g., a rounded profile along the gate lengthwise direction and a dog-bone profile along the gate widthwise direction), or combinations thereof. Referring to FIG. 8, FIG. 9N, FIG. 10N, and FIG. 11D, gate stacks 180 (e.g., gate dielectrics 182 and gate electrodes 184) are formed in gate openings 175 and/or gaps 378, such as described above with reference to FIG. 3Q, FIG. 4Q, and FIG. 5D. Device 300 may thus include at least one transistor T having improved performance, as described above.

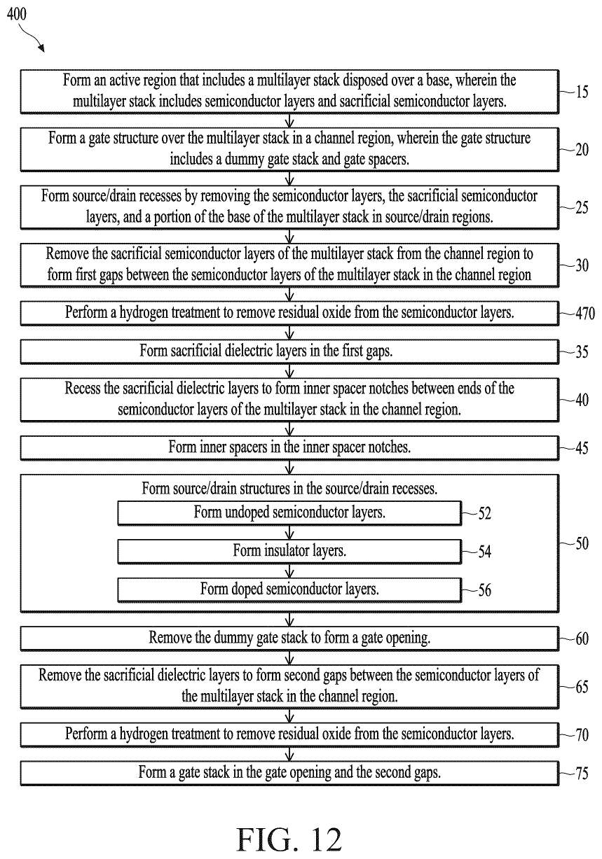

FIG. 12 is a flow chart of a method 400, in portion or entirety, for fabricating multigate devices according to various aspects of the present disclosure. Method 400 is similar in many respects to method 10. Accordingly, similar features in method 400 and method 10 are identified by the same reference numbers for clarity and simplicity. For example, method 400 includes forming an active region that includes a multilayer stack (including sacrificial semiconductor layers and semiconductor layers disposed over a base at block 15, forming a gate structure over the multilayer stack in a channel region at block 20, and forming source/drain recesses by removing the semiconductor layers, the sacrificial semiconductor layers, and a portion of the base in source/drain regions at block 25. Method 400 may further include removing the sacrificial semiconductor layers of the multilayer stack from the channel region to form first gaps between the semiconductor layers of the multilayer stack in the channel region at block 30 and forming sacrificial dielectric layers in the first gaps at block 35. In contrast to method 10, before forming sacrificial dielectric layers in the first gaps at block 35, method 400 includes performing a hydrogen treatment (e.g., a hydrogen anneal) to remove residual oxide from the semiconductor layers at block 470, which may be similar to the hydrogen treatment performed at block 70. Method 400 may then proceed similar to method 10 including, for example, recessing the sacrificial dielectric layers to form inner spacer notches between ends of the semiconductor layers of the multilayer stack in the channel region at block 40, forming inner spacers in the inner spacer notches at block 45, forming source/drain structures in the source/drain recesses at block 50 (which may include forming undoped semiconductor layers at block 52, forming insulator layers at block 54, and forming doped semiconductor layers at block 56), removing the dummy gate stack to form a gate opening at block 60, removing the sacrificial dielectric layers to form second gaps between the semiconductor layers of the multilayer stack in the channel region at block 65, performing a hydrogen treatment to remove residual oxide from the semiconductor layers at block 70, and forming the gate stack in the gate opening at block 75. Incorporating a hydrogen treatment after removing sacrificial semiconductor layers (i.e., block 470) may also improve channel surface roughness, among other advantages, as described herein. Additional processing is contemplated by the present disclosure. Additional steps may be provided before, during, and after method 400, and some of the steps described may be moved, replaced, or eliminated for additional embodiments of method 400. For example, in some embodiments, method 400 may include block 470 and omit block 70. In other words, fabrication of device 100 may include performing hydrogen treatment HT after removing sacrificial semiconductor layers 146 and before forming sacrificial oxide layers 146, but not after removing sacrificial oxide layers 146 and before forming gate stacks 180.

In some embodiments, a dielectric constant of CESL 172 is greater than a dielectric constant of ILD layer 174. In some embodiments, a dielectric constant of CESL 172 is less than a dielectric constant of gate dielectric 182. In some embodiments, a dielectric constant of ILD layer 174 is less than a dielectric constant of gate dielectric 182. In some embodiments, a dielectric constant of gate dielectric 182 is at least two times a dielectric constant of ILD layer 174. In some embodiments, a dielectric constant of ILD layer 174 is about 3 to about 5. In some embodiments, a dielectric constant of gate dielectric 182 is greater than a dielectric constant of gate spacers 134, CESL 172, and ILD layer 174. In such embodiments, a dielectric constant of CESL 172 may be greater than a dielectric constant of gate spacers 134 and/or a dielectric constant of ILD layer 174, and a dielectric constant of gate spacers 134 may be greater than, less than, or about the same as a dielectric constant of ILD layer 174.

The present disclosure provides for many different embodiments. Methods of fabricating multigate transistors with improved performance are disclosed herein. In some embodiments, a method includes forming a gate opening that exposes a multilayer stack. The multilayer stack includes semiconductor layers and sacrificial layers interleaving the semiconductor layers, and the method further includes extending the gate opening by selectively removing the sacrificial layers from the multilayer stack to form gaps between the semiconductor layers. The method further includes, after exposing the semiconductor layers to a hydrogen anneal process, forming a gate stack in the gate opening and in the gaps between the semiconductor layers. In some embodiments, the method further includes forming a dummy gate over the multilayer stack, and the gate opening is formed by removing the dummy gate.

In some embodiments, the method further includes tuning parameters of the hydrogen anneal process to remove residual oxide from surfaces of the semiconductor layers and/or tuning parameters of the hydrogen anneal process to modify profiles of the semiconductor layers. In some embodiments, the hydrogen anneal process is an H₂ anneal and/or a hydrogen radical anneal. In some embodiments, the H₂ anneal and/or the hydrogen radical is performed at an anneal temperature of about 600 °C to about 850 °C. In some embodiments, the gate opening exposes a first portion of the multilayer stack, and the method further includes, before forming the gate opening, forming source/drain recesses by removing second portions of the multilayer stack and forming source/drain structures in the source/drain recesses. The first portion of the multilayer stack may be disposed between the second portions of the multilayer stack.

In some embodiments, the sacrificial layers are first sacrificial layers, and the method further includes replacing the first sacrificial layers with second sacrificial layers before forming the gate opening, and the second sacrificial layers are removed from the multilayer stack to form the gaps between the semiconductor layers. In some embodiments, the gaps are first gaps, the hydrogen anneal process is a first hydrogen anneal process, and replacing the first sacrificial layers with the second sacrificial layers before forming the gate opening includes removing the first sacrificial layers to form second gaps between the semiconductor layers and forming the second sacrificial layers in the second gaps. In some embodiments, the second sacrificial layers are formed after exposing the semiconductor layers to a second hydrogen anneal process.

In some embodiments, a method includes forming a multilayer stack that includes semiconductor layers and sacrificial layers, and the sacrificial layers interleave the semiconductor layers. The method further includes, after removing the sacrificial layers, performing a hydrogen treatment to remove residual oxide from exposed surfaces of the semiconductor layers, and after performing the hydrogen treatment, forming a gate that wraps one or more of the semiconductor layers. In some embodiments, the residual oxide is residual germanium oxide, and the hydrogen treatment uses hydrogen radicals and/or H₂ to remove the residual germanium oxide. In some embodiments, the hydrogen treatment provides the semiconductor layers with inwardly bowing surfaces in a first cross-sectional view along a first direction (e.g., along a gate widthwise direction) and outwardly bowing surfaces in a second cross-sectional view along a second direction (e.g., along a gate lengthwise direction).

In some embodiments, the sacrificial layers are sacrificial semiconductor layers, and the method includes removing the sacrificial semiconductor layers after forming a gate opening, and the gate is formed in the gate opening. In some embodiments, the sacrificial layers are sacrificial dielectric layers, and the method includes removing the sacrificial dielectric layers after forming a gate opening, and the gate is formed in the gate opening. In some embodiments, the sacrificial layers are sacrificial semiconductor layers, and the method includes removing the sacrificial semiconductor layers before forming a gate opening, and the gate is formed in the gate opening. In such embodiments, the hydrogen treatment may be a first hydrogen treatment, and the method may further include after forming the first hydrogen treatment, forming sacrificial dielectric layers in gaps formed by removing the sacrificial semiconductor layers. In some embodiments, after removing the sacrificial dielectric layers, the method includes performing a second hydrogen treatment to remove residual oxide from exposed surfaces of the semiconductor layers. In some embodiments, after performing the second hydrogen treatment, the method includes forming the gate that wraps one or more of the semiconductor layers.

In some embodiments, a device structure includes a semiconductor layer, a first source/drain, a second source/drain, and a gate. The semiconductor layer extends lengthwise along a first direction between the first source/drain and the second source/drain. The gate is disposed over the semiconductor layer, and the gate extends lengthwise along a second direction different than the first direction. In a first cross-sectional view along the first direction, the semiconductor layer has inwardly bowing surfaces that abut the gate. In a second cross-sectional view along the second direction, the semiconductor layer has outwardly bowing surfaces that abut the gate. In some embodiments, in the first cross-sectional view along the first direction, a height of the semiconductor layer increases from a middle of the semiconductor layer to ends of the semiconductor layer. In some embodiments, in the second cross-sectional view along the second direction, the height of the semiconductor layer decreases from the middle of the semiconductor layer to the ends of the semiconductor layer. In some embodiments, in the first cross-sectional view along the first direction, the gate has outwardly bowing surfaces that abut the inwardly bowing surfaces of the semiconductor layer.

In some embodiments, a method includes forming channel layers and sacrificial layers in an alternating arrangement, removing the sacrificial layers, performing a hydrogen anneal process (e.g., to and/or on the channel layers) after removing the sacrificial layers, and forming a gate structure wrapping the channel layers. In some embodiments, the gate structure surrounds the channel layers. In some embodiments, the method includes, after removing the sacrificial layers and before performing the hydrogen anneal process, forming disposable oxide interposers between the channel layers and removing the disposable oxide interposers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a gate opening that exposes a multilayer stack, wherein the multilayer stack includes semiconductor layers and sacrificial layers interleaving the semiconductor layers;
extending the gate opening by removing the sacrificial layers from the multilayer stack to form gaps between the semiconductor layers; and
after exposing the semiconductor layers to a hydrogen anneal process, forming a gate stack in the gate opening and in the gaps between the semiconductor layers.

2. The method of claim 1, wherein the gate opening exposes a first portion of the multilayer stack, the method further comprising:
before forming the gate opening, forming source/drain recesses by removing second portions of the multilayer stack, wherein the first portion of the multilayer stack is disposed between the second portions of the multilayer stack; and
forming source/drain structures in the source/drain recesses.

3. The method of claim 1, wherein the sacrificial layers are first sacrificial layers, the method further comprising replacing the first sacrificial layers with second sacrificial layers before forming the gate opening, wherein the second sacrificial layers are removed from the multilayer stack to form the gaps between the semiconductor layers.

4. The method of claim 3, wherein:
the gaps are first gaps;
the hydrogen anneal process is a first hydrogen anneal process;
the replacing the first sacrificial layers with the second sacrificial layers before forming the gate opening includes removing the first sacrificial layers to form second gaps between the semiconductor layers and forming the second sacrificial layers in the second gaps; and
the method further includes forming the second sacrificial layers in the second gaps after exposing the semiconductor layers to a second hydrogen anneal process.

5. The method of claim 1, further comprising tuning parameters of the hydrogen anneal process to remove residual oxide from surfaces of the semiconductor layers.

6. The method of claim 1, further comprising tuning parameters of the hydrogen anneal process to modify profiles of the semiconductor layers.

7. The method of claim 1, wherein the hydrogen anneal process is an H₂ anneal performed at an anneal temperature of about 600 °C to about 850 °C.

8. The method of claim 1, wherein the hydrogen anneal process is a hydrogen radical anneal performed at an anneal temperature of about 600 °C to about 850 °C.

9. The method of claim 1, the method further comprising forming a dummy gate over the multilayer stack, wherein the gate opening is formed by removing the dummy gate.

10. A method comprising:
forming a multilayer stack that includes semiconductor layers and sacrificial layers, wherein the sacrificial layers interleave the semiconductor layers;
after removing the sacrificial layers, performing a hydrogen treatment to remove residual oxide from exposed surfaces of the semiconductor layers; and
after performing the hydrogen treatment, forming a gate that wraps one or more of the semiconductor layers.

11. The method of claim 10, wherein the sacrificial layers are sacrificial semiconductor layers, and the method includes removing the sacrificial semiconductor layers after forming a gate opening, wherein the gate is formed in the gate opening.

12. The method of claim 10, wherein the sacrificial layers are sacrificial dielectric layers, and the method includes removing the sacrificial dielectric layers after forming a gate opening, wherein the gate is formed in the gate opening.

13. The method of claim 10, wherein the sacrificial layers are sacrificial semiconductor layers, and the method includes removing the sacrificial semiconductor layers before forming a gate opening, wherein the gate is formed in the gate opening.

14. The method of claim 13, wherein the hydrogen treatment is a first hydrogen treatment, the method further comprising:
after forming the first hydrogen treatment, forming sacrificial dielectric layers in gaps formed by removing the sacrificial semiconductor layers;
after removing the sacrificial dielectric layers, performing a second hydrogen treatment to remove residual oxide from exposed surfaces of the semiconductor layers; and
after performing the second hydrogen treatment, forming the gate that wraps one or more of the semiconductor layers.

15. The method of claim 10, wherein the residual oxide is residual germanium oxide, and the hydrogen treatment uses hydrogen radicals to remove the residual germanium oxide.

16. The method of claim 10, wherein the residual oxide is residual germanium oxide, and the hydrogen treatment uses H₂ to remove the residual germanium oxide.

17. The method of claim 10, wherein the performing the hydrogen treatment provides the semiconductor layers with inwardly bowing surfaces in a first cross-sectional view along a gate widthwise direction and outwardly bowing surfaces in a second cross-sectional view along a gate lengthwise direction.

18. A device structure comprising:
a semiconductor layer that extends lengthwise along a first direction between a first source/drain and a second source/drain;
a gate disposed over the semiconductor layer, wherein the gate extends lengthwise along a second direction different than the first direction; and
wherein:
in a first cross-sectional view along the first direction, the semiconductor layer has inwardly bowing surfaces that abut the gate, and
in a second cross-sectional view along the second direction, the semiconductor layer has outwardly bowing surfaces that abut the gate.

19. The device structure of claim 18, wherein:
in the first cross-sectional view along the first direction, a height of the semiconductor layer increases from a middle of the semiconductor layer to ends of the semiconductor layer; and
in the second cross-sectional view along the second direction, the height of the semiconductor layer decreases from the middle of the semiconductor layer to the ends of the semiconductor layer.

20. The device structure of claim 18, wherein in the first cross-sectional view along the first direction, the gate has outwardly bowing surfaces that abut the inwardly bowing surfaces of the semiconductor layer.
